(19) United States
(12) Patent Application Publication
(10) Pub. No.: US 2015/0136209 A1
(43) Pub. Date: May 21, 2015

(54) POLYIMIDE LAYER-CONTAINING FLEXIBLE SUBSTRATE, POLYIMIDE LAYER-CONTAINING SUBSTRATE FOR FLEXIBLE SOLAR CELL, FLEXIBLE SOLAR CELL, AND METHOD FOR PRODUCING SAME

(71) Applicant: NIPPON STEEL & SUMIKIN CHEMICAL CO., LTD., Tokyo (JP)

(72) Inventors: Kouichi Hattori, Kisaradu-shi (JP); Katsufumi Hiraishi, Tokyo (JP); Takuhei Ohta, Tokyo (JP); Shinichi Terashima, Tokyo (JP); Hideaki Suda, Tokyo (JP); Masao Kurosaki, Tokyo (JP); Masamoto Tanaka, Tokyo (JP); Shuji Nagasaki, Tokyo (JP); Atsushi Mizuyama, Tokyo (JP)

(73) Assignee: NIPPON STEEL & SUMIKIN CHEMICAL CO., LTD., Tokyo (JP)

(21) Appl. No.: 14/400,720

(22) PCT Filed: May 14, 2013
(86) PCT No.: PCT/JP2013/063452

§ 371 Date: Nov. 12, 2014

(30) Foreign Application Priority Data
May 14, 2012 (JP) 2012-110841

(51) Int. Cl. H01L 31/0392; C09D 179/08; H01L 31/18

(52) U.S. Cl. CPC H01L 31/03926; H01L 31/1884; H01L 31/18; C09D 179/08
USPC 136/252; 438/98; 427/74; 205/196

(57) ABSTRACT

A flexible substrate has heat resistance to endure the high temperature such as sintering of a photovoltaic conversion layer of a compound-type thin film solar cell, can prevent permeation and/or diffusion of metal into the photovoltaic conversion layer, and can be used for many applications. The polyimide layer-containing flexible substrate has a metal substrate of metal foil made of ordinary steel or stainless steel having a coefficient of thermal expansion in a plane direction of not more than 15 ppm/K, or a metal substrate of metal foil made of that ordinary steel or stainless steel on the surface of which a metal layer comprising one of copper, nickel, zinc, or aluminum or an alloy layer of the same is provided, over which a polyimide layer having a layer thickness of 1.5 to 100 μm and a glass transition point temperature of 300 to 450° C. is formed.

### TECHNICAL FIELD

The present invention relates to a polyimide layer-containing flexible substrate which is suitable as a solar cell substrate and printed circuit board, a substrate for a polyimide layer-containing flexible solar cell, a flexible solar cell using the same, and methods of production of the same.

### BACKGROUND ART

As solar cells, a single crystal silicon solar cell using silicon, a polycrystal silicon solar cell, a compound semiconductor solar cell, a dye-sensitized solar cell, an organic thin film solar cell, and various other types have been developed. In these solar cells, not only a high photovoltaic conversion efficiency, but also light weight, high durability, and further flexibility enabling free bendability have been demanded along with their spread to a variety of applications.

Along with the rising need for this high flexibility, a compound-based thin film solar cell using a substrate having pliability is attracting attention. Hithertofore, a glass substrate has been mainly used as the substrate for a thin film solar cell. However, a glass substrate had the defect that it was fragile and required great caution in handling and was poor in flexibility. On the other hand, increased size, increased area, and lighter weight have been desired from solar cells. For this reason, as described above, light weight, flexible substrates taking the place of glass will probably be sought more and more in the future.

As the compound-based thin film solar cells, there are known ones which use CdS/CdTe, CIS[CuInS₂], CIGS[Cu(In,Ga)Se₂], and other compound semiconductors as photovoltaic conversion layers (light-absorbing layers). For these compound-based thin film solar cells, a resin substrate, aluminum alloy substrate, and so on have been proposed as a substrate which is light in weight and satisfies the requirement of flexibleness. Note that when an aluminum alloy or other metal substrate is used as a substrate of an integrated solar cell, an anodic oxide film or other insulating layer is provided between the substrate and the photovoltaic conversion layer. For this reason, the material configuring the substrate ends up becoming multilayered. The difference of coefficient of thermal expansions of the ingredient materials ends up causing the multilayer member to potentially easily peel apart. Accordingly, when a high level flexible deformability, which was not regarded as an issue in the past, is demanded in the future, in a conventional multilayer base material, there is an apprehension of the multilayer member peeling apart due to distortion caused along with deformation.

When forming a thin film of the compound-based semiconductor described above as a photovoltaic conversion layer, the compound is placed on the substrate and is sintered at 350° C. to 600° C. in accordance with the type of the compound. For example, for forming a CIGS layer (thin film) in continuous production, preferably the sintering is carried out at 350° C. to 550° C. at a line speed of 4 to 20 m/min. accordingly, heat resistance against this temperature is demanded from the substrate material. In order to raise the conversion efficiency of CIGS as such as possible, raising the above film formation temperature is effective. Therefore, desirably the substrate material has enough heat resistance to endure 500° C. However, general use materials such as tin and zinc respectively have melting points of 232° C. and 420° C. Therefore, when these metals are used as the material of the metal substrate, the metal ends up melting at the time of formation of the CIGS layer, so this is not preferable. On the other hand, aluminum, copper, nickel, and steel respectively have melting points of 660° C., 1084° C., 1455° C., and more than 1200° C. (according to the composition in the steel), therefore they are suitable for this application.

Note that, aluminum by itself is insufficient in high temperature strength, therefore shape retention at the time of the sintering is difficult. Therefore, in order to impart high temperature strength, an aluminum alloy is used as the metal substrate. For example, PLT 1 discloses use of an aluminum alloy containing a plurality of metal elements such as Si, Fe, Cu, Mn, Sc, and Zr.

With the use of these metals or alloys, however, even when high precision rolling is carried out, only a metal surface with a smoothness of an Ra of about 30 on can be obtained. Therefore, projections end up remaining on the substrate surface. For this reason, when these metals or alloys are used as the substrate, if stress is unintentionally applied, the stress is concentrated at the tops of the projections and the circuit of the solar cell laid over that is damaged, so this is not preferred. That is, a substrate made of conventional metals or alloys is not sufficient in smoothness. Alternatively, even if aluminum is selected as the plating species and the aluminum is anodized after plating, there is the problem that the added elements described before form intermetallic compounds and become defects of the insulating film of the anodic oxide coating and thus lower the insulation property. PLT 2 discloses use of an aluminum alloy containing 2.0 to 7.0 wt % of magnesium in order to prevent a drop in the insulation property.

Further, PLT 3 discloses a flexible dye-sensitized solar cell module which uses a resin substrate in place of a substrate constituted by aluminum alloy and uses a flexible connector made of electrolytic copper foil which is laminated on its two sides by flexible PET resin to thereby impart flexibility. The defect of a resin substrate is its lack of heat resistance, therefore the above PLT 3 uses an expensive resin in order to secure heat resistance. However, when considering the demands for such greater reduction of costs in recent solar cells, a cheap polyimide is preferably used, but in general, the glass transition point of polyimide stops at about 300° C., therefore the high temperature process explained above cannot be withstood. Further, a resin alone does not have a sufficient heat releasing property and is insufficient in strength as well. Therefore, in order to secure a heat releasing property, preferably a multilayer structure of a metal foil and resin layer is employed.

In the case of a compound-based thin film solar cell, as explained above, for the formation of the photovoltaic conversion layer, a sintering process of a temperature of 300 to 600° C. is necessary. At this time, if using an aluminum or other metal alloy as the substrate, there is the problem that the metal ingredients will pass through the insulating layer and permeate and/or diffuse into the photovoltaic conversion layer and thereby exert an adverse influence upon the photovoltaic efficiency. The art of PLT 2 cannot solve this problem. Further, in the art of PLT 3, there is flexibility at the flexible connector portion, but the substrate as a whole lacks flexibility. Further, there is also the defect of insufficient heat resistance at the time of sintering of the photovoltaic conversion layer.

PLT 4 discloses a method of production of a flexible multilayer substrate comprising a conductor on which a polyimide resin layer is formed. However, it is being demanded to maintain high flexibility while raising the high heat resistance and smoothness and resistance against diffusion of metal.

### CITATIONS LIST

### Patent Literature

PLT 1: Japanese Patent Publication No. 2008-81794A

PLT 2: Japanese Patent Publication No. 2011-190466A

PLT 3: Japanese Patent Publication No. 2011-8962A

PLT 4: Japanese Patent Publication No. 2006-62187A

### SUMMARY OF INVENTION

### Technical Problem

An object of the present invention is to provide a flexible substrate which has enough heat resistance to endure the high temperature for example at the time of sintering of a photovoltaic conversion layer of a thin film solar cell, is excellent in smoothness, can prevent permeation and/or diffusion of metal into the photovoltaic conversion layer, and can be used for many applications. Further, another object is to provide a flexible solar cell which uses that substrate. That is, the subject of the present invention is to provide a flexible substrate which maintains high flexibility while achieving both high heat resistance and excellent smoothness and prevention of diffusion of metal.

### Solution to Problem

The inventors engaged in intensive studies in order to solve the above problems. As a result, they found that the above problems could be solved by employing a polyimide layer-containing flexible substrate comprising a metal substrate of metal foil made of ordinary steel or stainless steel having a coefficient of thermal expansion in a plane direction of not more than 15 ppm/K, or a metal substrate of metal foil made of that ordinary steel or stainless steel on the surface of which a metal layer comprising one of copper, nickel, zinc, or aluminum or an alloy layer of the same is provided, over which a polyimide layer exhibiting specific physical properties is formed and thereby completed the present invention.

That is, a polyimide layer-containing flexible substrate of the present invention has a metal substrate of metal foil made of ordinary steel or stainless steel having a coefficient of thermal expansion in a plane direction of not more than 15 ppm/K and a polyimide layer which is formed on the metal substrate, has a layer thickness of 1.5 to 100 μm, and has a glass transition point temperature of 300 to 450° C.

Alternatively, a polyimide layer-containing flexible substrate of the present invention has a metal substrate of metal foil made of ordinary steel or stainless steel having a coefficient of thermal expansion in a plane direction of not more than 15 ppm/K on the surface of which a metal layer comprising one of copper, nickel, zinc, or aluminum or an alloy layer of the same is provided and a polyimide layer which is formed on the metal layer or the alloy layer, has a layer thickness of 1.5 to 100 μm, and has a glass transition point temperature of 300 to 450° C.

In the polyimide layer-containing flexible substrate of the present invention described above, preferably the metal layer or the alloy layer is an aluminum layer or aluminum alloy layer.

In the polyimide layer-containing flexible substrate of the present invention described above, preferably the coefficient of thermal expansion in the plane direction of the polyimide layer at 100° C. to 250° C. is 15×10⁻⁶/K or less.

In the polyimide layer-containing flexible substrate of the present invention described above, preferably the surface roughness of the surface of the polyimide layer on the side which does not contact the metal substrate is 10 nm or less.

In the polyimide layer-containing flexible substrate of the present invention described above, preferably, after heat treatment at 400° C. for 10 minutes, the content of the metal which forms the metal substrate on the surface of the polyimide layer on the side which does not contact the metal substrate is less than a detection limit in measurement according to an emission spectrum detection method.

Further, a substrate for a polyimide layer-containing flexible solar cell of the present invention is configured by using the above polyimide layer-containing flexible substrate.

Further, a flexible solar cell of the present invention has the above substrate for a polyimide layer-containing flexible solar cell, a bottom electrode which is formed on the polyimide layer, a photovoltaic conversion layer which is formed on the bottom electrode, and a transparent electrode which is formed on the photovoltaic conversion layer.

In the flexible solar cell of the present invention described above, preferably, in the photovoltaic conversion layer, the content of the metal which forms the metal substrate is less than a detection limit in measurement according to an emission spectrum detection method.

In the flexible solar cell of the present invention described above, preferably the content of the metal which forms the metal substrate in the surface of the polyimide layer on the side which does not contact the metal substrate is less than a detection limit in measurement according to the emission spectrum detection method.

Further, a method of production of a polyimide layer-containing flexible substrate of the present invention has a step of coating a polyimide precursor solution on a metal substrate of metal foil made of ordinary steel or stainless steel having a coefficient of thermal expansion in a plane direction of not more than 15 μppm/K and a step of heat treating the polyimide precursor solution to cure it by drying and imidization and forming a polyimide layer having a layer thickness of 1.5 to 100 μm and having a glass transition point temperature of 300 to 450° C.

Alternatively, a method of production of a polyimide layer-containing flexible substrate of the present invention has a step of forming on the surface of metal foil made of ordinary steel or stainless steel having a coefficient of thermal expansion in a plane direction of not more than 15 ppm/K a metal layer comprising one of copper, nickel, zinc, or aluminum or an alloy layer of the same to form a metal substrate, a step of coating a polyimide precursor solution on the metal layer or the alloy layer of the same, and a step of heat treating the polyimide precursor solution to cause curing by drying and imidization and thereby to form a polyimide layer having a layer thickness of 1.5 to 100 μm and glass transition point temperature of 300 to 450° C.

The method of production of a polyimide layer-containing flexible substrate of the present invention described above preferably forms an aluminum layer or aluminum allay layer as the metal layer or the alloy layer in the step of forming on the surface of the metal foil the metal layer or alloy layer of the same to form the metal substrate.

Further, the method of production of a substrate for a polyimide layer-containing flexible solar cell of the present invention uses the method of production of a polyimide layer-containing flexible substrate disclosed above to produce a substrate for a polyimide layer-containing flexible solar cell which uses that polyimide layer-containing flexible substrate.

Further, the method of production of a substrate for a polyimide layer-containing flexible solar cell of the present invention has a step of forming a bottom electrode on a polyimide layer of a substrate for a polyimide layer-containing flexible solar cell which is produced according to the method of production of the substrate for a polyimide layer-containing flexible solar cell described above, a step of forming a photovoltaic conversion layer on the bottom electrode, and a step of forming a transparent electrode on the photovoltaic conversion layer.

Here, the “emission spectrum detection method” means the following method. That is, a Glow Discharge Light Spectrum Analyzer GD-PROFILER2 (made by HORIBA Ltd. (made by HORIBA JOBIN YVON SAS) is used to measure the polyimide layer and photovoltaic conversion layer to determine whether the spectrum of each metal forming the metal substrate is detected. Specifically, (1) for a standard sample of the metal element, the spectrum is measured while changing the concentration, and a calibration curve (output voltage (V)-concentration (wt %) for conversion of the metal element concentration is prepared. The calibration curve is prepared for each metal element targeted. (2) For each sample taken from the polyimide layer and photovoltaic conversion layer, the emission spectrum of the target metal element is measured by the analyzer. (3) The peak intensity of the emission spectrum of each metal element is detected by the output voltage (V) of a detector, therefore the concentration of the metal element is read from the above calibration curve. (4) A concentration less than 0.1 wt % is judged as less than the detection limit.

### Advantageous Effect of Invention

The polyimide layer-containing flexible substrate of the present invention has enough heat resistance to endure the high temperature for example at the time of sintering of a photovoltaic conversion layer of a thin film solar cell and can prevent permeation and/or diffusion of metal into the photovoltaic conversion layer. Accordingly, it can be used for many applications such as solar cell-use substrates and printed circuit boards. Further, in the flexible solar cell in the present invention, the metal ingredients in the metal substrate does not permeate and/or diffuse into the photovoltaic conversion layer or electrode, therefore a good photovoltaic efficiency can be obtained.

### BRIEF DESCRIPTION OF DRAWINGS

FIG. 1 is a cross-sectional view of a polyimide layer-containing flexible substrate of an embodiment of the present invention.

FIG. 2 is a cross-sectional view of a flexible solar cell in an embodiment of the present invention.

FIG. 3 is a flow chart which shows a method of production of a polyimide layer-containing flexible substrate in an embodiment of the present invention.

FIG. 4 is a flow chart which shows a method of production of a flexible solar cell in an embodiment of the present invention.

### DESCRIPTION OF EMBODIMENTS

Below, embodiments of the present invention will be explained with reference to the drawings.

### First Embodiment

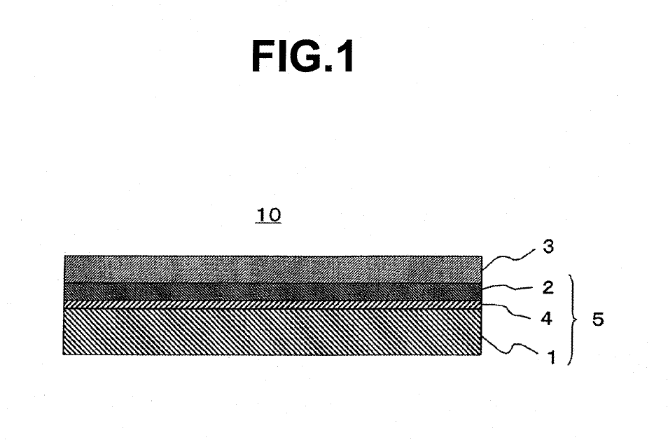

An embodiment of the present invention will be explained by using FIG. 1. A first embodiment of the present invention is a polyimide layer-containing flexible substrate 10 which has a metal substrate configured by a metal foil 1 of ordinary steel or stainless steel (hereinafter, abbreviated as SUS) having a coefficient of thermal expansion in a plane direction of not more than 15 ppm/K and a polyimide layer 3 formed on the metal substrate and having a layer thickness of 1.5 to 100 μm and a glass transition point temperature of 300 to 450° C.

Polyimide alone cannot secure a barrier property, particularly a barrier property against moisture, oxygen, or other gas ingredient, therefore unless a barrier film is separately provided, the function falls due to invasion of a gas ingredient or other ingredient derived from an external environment, therefore this is insufficient in suitability as the substrate of a device. Further, polyimide alone is not always sufficient in strength, so depending on the degree of dynamic load, there is a risk of breakage or the like even in handling of extent of processing taking it up around a roll. Achievement of both durability against dynamic load and flexibility over a sufficiently broad range cannot be obtained. On the other hand, with metal alone, the barrier property and strength are sufficient, but the smoothness is about Ra>20 nm or not good. Therefore, when made a multilayer structure of a metal substrate and a polyimide layer, the required barrier property and strength can be secured by making up for the shortage of the barrier property and strength of the polyimide layer by the metal substrate, therefore the apprehension of breakage as in glass is eliminated, the flexibility can be maintained by making the metal substrate a metal foil layer and, in addition, by stacking the polyimide layer, a high smoothness comparable to a glass substrate (Ra≦10 nm) can be realized.

However, even in this multilayer member, since the polyimide layer does not have heat resistance, the polyimide layer ends up being burnt or deformed under a high temperature process as in the manufacturing process of a CIGS. Therefore, it is possible to employ a multilayer structure of a metal substrate and a polyimide layer which has a high temperature heat resistance of a glass transition point temperature of 300 to 450° C. to provide flexibility, smoothness, and heat resistance. This is because by making the polyimide layer 3 which is formed on the metal layer 2 one with a glass transition point of 300° C. or more and making it one of 450° C. or less from the point of practicability such as manufacturing cost, when applied to a flexible solar cell, it becomes possible to suppress softening, deformation, breakdown, etc. at a temperature at the time of sintering of the photovoltaic conversion layer.

However, even in this multilayer member, if the heat resistant polyimide layer is thick or the coefficient of thermal expansion of the heat resistant polyimide layer and the coefficient of thermal expansion of the metal substrate greatly differ, the heat resistant polyimide layer and the metal substrate end up peeling apart. In order to solve this problem, the polyimide layer is made thinner to 1.5 to 100 μm to suppress warping of the heat resistant polyimide layer and further the coefficient of thermal expansion of the metal substrate is made the same extent as the coefficient of thermal expansion of the heat resistant polyimide layer, specifically 15 ppm/K or less. In order to control the coefficient of thermal expansion of ordinary steel or SUS as described above, it is sufficient to use cold-rolled steel sheet as the ordinary steel or a ferrite-based as the SUS. Further, for example, by rolling them, it is sufficient to make a (100) [011] structure in the plane. Specifically, the rolling reduction from the starting material to the completion of rolling of the foil is suitably controlled to 30% or more. Further, the extent of formation of the structure should be suitably determined so that the degree of aggregation in the plane becomes 30% or more. For the observation of that, suitably use is made of EBSD (Electron Back Scattered Diffraction) since though it is simple, a correct value is obtained. The thickness of the metal substrate which is 10 to 200 μm is preferred since the flexible substrate can be lightened in weight and the weight of the solar cell can be reduced.

When a special corrosion resistance is not demanded, a structure of a metal substrate made of a metal foil of ordinary steel on which heat resistant polyimide is directly laminated may be employed. However, where use outdoors is sought, with ordinary steel, the corrosion resistance is not sufficient. Therefore, it is sufficient to use a structure using SUS foil as the metal substrate.

In SUS foil, even when the end faces are exposed, since the SUS itself has corrosion resistance, it is not always necessary to protect the end faces by coating for imparting or improving corrosion resistance.

### Second Embodiment

It is known that, in a CIGS solar cell, if diffusion of metal elements, particularly Fe atoms, into a power generation layer occurs, the conversion efficiency falls. When not glass, but a metal is used for the base material, prevention of diffusion of Fe atoms becomes particularly important. In order to solve this problem, as a second embodiment of the present invention, rather than directly laminating a heat resistant polyimide on the metal foil 1 made of ordinary steel or SUS, a polyimide layer-containing flexible substrate comprising a metal substrate which is provided with a metal foil 1 made of ordinary steel or SUS on the surface of which a metal layer made of one of copper, nickel, zinc, or aluminum or an alloy layer of the sane (hereinafter referred to as a “metal layer or alloy layer 2”) and a polyimide layer 3 which is formed on the metal layer or alloy layer 2, has a layer thickness of 1.5 to 100 μm, and has a glass transition point temperature of 300 to 450° C. may be provided. This is due to the fact that due to the provision of a layer not containing Fe atoms between the metal substrate and the polyimide layer, the diffusion length of Fe atoms becomes longer and the diffusion of Fe atoms into the power generation layer is suppressed. Except for this, the configuration is the sane as that of the first embodiment.

The metal layer mast be a metal which does not melt when producing the compound semiconductor and is preferably aluminum having a melting point of 660° C., copper having a melting point of 1084° C., or nickel having a melting point of 1455° C. Aluminum is more preferred in the point that cheap electroless plating can be utilized. In a case where a CdTe layer is used as the power generation layer of the solar cell, zinc having a melting point of 420° C. can be utilized as well since the process temperature is low. For the formation of the metal layer, there are plating, vapor deposition, CVD, etc. However, plating is the most preferred. At the end faces of the metal substrate having the metal layer or alloy layer 2, the metal foil 1 (ferrite) is exposed. Therefore, in order to raise the corrosion resistance, preferably the end faces are coated by a resin or the like.

The plating may be carried out after the formation of the metal foil 1 or may be carried out on the base material of the metal plate before rolling the foil. In the latter case, rolling is carried out after plating to form a metal foil provided with a plating layer. As the metal other than aluminum in the case where an aluminum alloy is used, Mg, Si, Zn, Ca, Sn, etc can be used. The content of these metals in the aluminum alloy is preferably 2 to 15 wt %. This is because both high heat resistance and corrosion resistance can be made realized. Below, the metal foil 1 on which the metal layer or alloy layer 2 is formed by plating or the like will be referred to as a “metal substrate 5 provided with a metal layer or alloy layer”. When plating Cu, Ni, or Zn, suitably electroplating or electroless plating is carried out by using a general plating bath of Cu, Ni, or Zn because of the abundance of past experience with it.

The thickness of the metal layer or alloy layer 2 formed by the plating is preferably 0.1 to 30 μm. This is because, if it is less than 0.1 μm, a sufficiently preferable effect of corrosion resistance is not obtained, so there is a risk of oxidation of the metal foil 1. On the other hand, a large amount of the plating species must be coated when the thickness is over 30 μm, therefore the production cost becomes high. Preferably the thickness of the metal layer or alloy layer 2 formed by the plating is made 1 to 30 μm, more preferably the thickness of the metal layer or alloy layer 2 formed by the plating is made 3 to 30 μm, and most preferably the thickness of the metal layer or alloy layer 2 formed by the plating is made 8 to 30 μm since a sufficient corrosion resistance effect is obtained.

### Third Embodiment

With metal foil provided with an aluminum (hereinafter, sometimes abbreviated as “Al”)-containing metal layer which is produced according to the prior art, the flexibility tends to fall compared with metal foil provided with a Cu-containing, Ni-containing, or Zn-containing metal layer. This is because, generally, when a metal layer or alloy layer 2 which is formed by aluminum or by plating mainly using aluminum is formed on a ordinary steel layer or SUS layer, an Fe—Al-based alloy layer 4 (for example FeAl₃, Fe₂Al₈Si, FeAl₅Si, or another intermetallic compound) is formed in a layer state at an interface between the metal foil 1 made of ordinary steel layer or SUS and the Al-containing metal layer or alloy layer 2. This Fe—Al-based alloy layer 4 is very hard and brittle. Therefore, if the plated steel or SUS is subjected to extreme elastic plastic deformation at handling or the like, this Fe—Al-based alloy layer 4 cannot follow the deformation of the metal foil layer 1 and, finally, sometimes causes peeling between the metal foil 1 and the Al-containing metal layer or alloy layer 2 and breakage of the Al-containing metal layer or alloy layer 2. In order to solve this problem, in the third embodiment of the present invention, a metal substrate 5 configured by a metal foil 1 as shown below on which an Al-containing metal layer or alloy layer 2 is formed. By using the metal substrate 5 provided with the Al-containing metal layer or alloy layer 2 according to the present embodiment, the flexibility can be satisfied.

Note that, the metal substrate 5 provided with the Al-containing metal layer or alloy layer 2 can be evaluated for elastic plastic deformation property by using a peel test which will be explained later as an indicator. When it has a high level elastic plastic deformation property, a good adhesiveness between the Al-containing metal layer or alloy layer 2 with the metal foil 1 without peeling of the Al-containing metal layer or alloy layer 2 is obtained in the peel test.

### Embodiment 1

If, after laminating the polyimide layer 3, the Fe—Al-based alloy layer 4 which is formed at the interface between the metal foil 1 and the Al-containing metal layer or alloy layer 2 has a thickness of 0.1 to 8 μm and further contains an Al₇Cu₂Fe intermetallic compound or an intermetallic compound of FeAl₃ groups, a further higher level of the elastic plastic deformation property explained before can be satisfied, therefore this is preferred. This effect is not satisfactorily obtained if only the polyimide layer 3 is laminated or only the Fe—Al-based alloy layer 4 is controlled as explained above. This is obtained the first time when both are simultaneously achieved. Details of the reason are still being clarified, but it is believed that peeling or breakage is prevented by mitigating the stress which is generated in a multilayer member by the coefficient of thermal expansion of the Fe—Al-based alloy layer 4 which is controlled as described above becomes an intermediate value between the coefficient of thermal expansion in a plane direction of the polyimide layer 3 and the coefficient of thermal expansion of the base material of the steel layer 1. This Al₇Cu₂Fe intermetallic compound or intermetallic compound of FeAl₃ groups is preferably contained in the Fe—Al-based alloy layer 4 in an amount of 50% or more in terms of the area percentage, more preferably is contained in amount of 90% or more.

Here, the “intermetallic compound of FeAl₃ groups” means an intermetallic compound comprising an FeAl₃ intermetallic compound into which an element forming a system (for example, Si or Cu or another element forming an Al-containing metal layer, Ni or Cu or other element forming a preplating film, or C, P, Cr, Ni, No, or other element forming the steel layer 1) forms a solid solution or an intermetallic compound formed from the above element forming a system and Fe and Al in a new ratio of composition. This intermetallic compound of FeAl₃ groups is particularly preferably an intermetallic compound of FeAl₃ groups in which Cu forms a solid solution or intermetallic compound of FeAl₃ groups in which Ni forms a solid solution. However, as will be explained later, if the Vicker's hardness of this Fe—Al-based alloy layer 4 becomes about 200 to 600 Hv, the element forming the solid solution is not limited to Ni or Cu.

A method of forming an Fe—Al-based alloy layer 4 containing the above Al₇Cu₂Fe intermetallic compound or intermetallic compound of FeAl₃ groups is a method comprising plating ordinary steel with Al-containing plating during which making the element forming the system diffuse from the Cu or Ni preplating film which will be explained later, steel layer 1, and Al-containing metal layer 2 so as to alloy the Fe and Al. In this way, in order to cause the suitable formation of the Fe—Al-based alloy layer 4 containing the above Al₇Cu₂Fe intermetallic compounds or intermetallic compound of FeAl₃ groups, preferably, before the Al-containing plating, a preplating film of Cu or Ni is formed on the ordinary steel in advance so as to form a Cu or Ni preplating in advance on the steel layer 1. However, the Fe—Al-based alloy layer 4 can be formed by diffusion of the elements forming the metal foil 1 and metal layer or alloy layer 2 containing Al as well, therefore the Cu or Ni preplating film is not an indispensable composition.

In this Fe—Al-based alloy layer 4 containing the Al₇Cu₂Fe intermetallic compound or intermetallic compound of FeAl₃ groups, the Vicker's hardness becomes 500 to 600 Hv. In the conventional hard and brittle Fe—Al-based alloy layer 4 explained above, the Vicker's hardness is about 900 Hv. In this way, by controlling the Fe—Al-based alloy layer 4 to a relatively soft layer, it becomes possible to improve the elastic plastic deformation property of the metal substrate 5 provided with the Al-containing metal layer or alloy layer 2. Further, if the thickness of the Fe—Al-based alloy layer 4 is less than 0.1 μm, the above effect as the soft Fe—Al-based alloy layer 4 cannot be obtained. On the other hand, when the thickness is over 8 μm, the diffusion of the elements forming the system advances too much, therefore it becomes easy to generate Kirkendall voids, so this is not preferred.

In order to further raise the elastic plastic deformation property of the metal substrate 5 provided with the Al-containing metal layer or alloy layer 2, preferably the thickness of the Fe—Al-based alloy layer 4 is made 0.1 to 8 μm. Further, when its thickness is made 3 to 8 μm, the corrosion resistance of the metal substrate 5 provided with the Al-containing metal layer or allay layer 2 further rises, so this is preferred. Further, if its thickness is made 3 to 5 μm, the high level two effects are simultaneously obtained, therefore this is the most preferred.

Further, when the Cu or Ni preplating film is made to remain with a thickness of 2 to 10 μm between the metal foil 1 and the Fe—Al-based alloy layer 4 to form a Cu layer or Ni layer, the adhesiveness between the metal foil 1 and the Fe—Al-based alloy layer 4 further increases and the elastic plastic deformation property is improved, therefore this is preferred. As a result, it becomes hard for peeling of the Fe—Al-based alloy layer 4 to occur even if severe processing is carried out at press-forming or deep drawing or the like.

Even if the above Cu layer or Ni layer is present between the metal foil 1 and the Fe—Al-based alloy layer 4, the effect of the Fe—Al-based alloy layer 4 explained above is not obstructed. However, if the thickness of the Cu layer or Ni layer is less than 2 μm, the effect of improving the adhesiveness between the metal foil 1 and the Fe—Al-based alloy layer 4 is not obtained. Further, if the thickness is over 10 μm, the above effect is saturated and further the cost of forming the preplating film rises as well, therefore this is not preferred.

Next, the methods of production of the metal foil 1, the Al-containing metal layer or alloy layer 2, and the metal substrate 5 provided with the Al-containing metal layer or alloy layer 2 which has the former two according to the present embodiment will be explained in detail.

For example, ordinary steel (carbon steel) plate having any ingredients is rolled as a first rolling treatment to a thickness of 200 to 500 μm. This rolling method may be either of hot rolling or cold rolling. If the steel sheet is less than 200 μm in thickness, it is too thin, therefore handling at the time of post-treatment is difficult. Further, if the steel sheet is over 500 μm in thickness, it is too thick, therefore too much load is applied in the post-process. If taking productivity in the post-processing into account, as the first rolling treatment, preferably rolling is carried out to a thickness of 250 to 350 μm.

The steel sheet after the above first rolling treatment is preplated by applying Cu or Ni preplating, plated by applying Al-containing plating, and treated by second rolling treatment. The order of these treatments may be either of (1) preplating, plating, and then second rolling treatment, (2) preplating, second rolling treatment, and plating, or (3) second rolling treatment, preplating, and then plating.

As the above preplating, electroplating or electroless plating is performed by using a plating bath of Cu or Ni. In both of the cases of the Cu preplating film and Ni preplating film, when the initial thickness of the preplating film is made 0.05 to 4 μm, the thickness of the Fe—Al-based alloy layer 4 which is formed between the metal foil 1 and the Al-containing metal layer or alloy layer 2 when forming the Al-containing metal layer or alloy layer 2 by plating becomes 0.1 to 8 μm. For example, where it is desired to control the thickness of the Fe—Al-based alloy layer 4 which is formed at the plating of the Al-containing metal layer or alloy layer 2 to the above optimal 3 to 5 μm, the initial thickness of the preplating film may be controlled to 1.5 to 2.5 μm.

Further, in order to leave the Cu or Ni preplating film between the metal foil 1 and the Fe—Al-based alloy layer 4 to arrange the Cu layer or Ni layer there, the initial thickness of the preplating film may be made 4 μm as the standard and the film may be formed thicker by the amount of the remaining thickness. The Cu or Ni preplating film having a thickness less than 4 μm is diffused into the Fe—Al-based alloy layer 4 which is formed at the Al-containing plating and disappears. In the preplating film which is formed over 4 μm, only the portion having a thickness obtained by subtracting 4 μm frau the film thickness remains and becomes the Cu layer or Ni layer. For example, in order to make a Cu layer or Ni layer having a thickness of 5 μm remain between the steel layer 1 and the Fe—Al-based alloy layer 4, the initial thickness of the preplating film may be made a thickness of 4+5=9 μm.

When it is desired to form the above Fe—Al-based alloy layer 4 without performing preplating, the compositions of ingredients of the metal foil 1 and Al-containing metal layer or alloy layer 2 may be suitably adjusted.

As the plating for forming the Al-containing metal layer or allay layer 2 by plating, electroplating and electroless plating can be used.

As the second rolling treatment, rolling is carried out so that the thickness becomes 10 to 250 μm. The rolling conditions of this may be ordinary rolling conditions. If the metal substrate 5 provided with the Al-containing metal layer or alloy layer 2 is less than 10 μm in thickness, it is too thin as a metal substrate 5, therefore the strength insufficient, so this is not preferred. Further, if the metal substrate 5 provided with the Al-containing metal layer or allay layer 2 is over 250 μm in thickness, it is too thick as a metal substrate 5 and is too heavy, so this is not preferred.

### Embodiment 2

The inventors engaged in intensively studies and as a result found that by granular dispersion of the Fe—Al-based alloy layer 4 between the Al-containing metal layer or alloy layer 2 and the metal foil 1, conventional breakage and peeling of the Al-containing metal layer or alloy layer 2 were suppressed and the metal foil 1 and the Al-containing metal layer or alloy layer 2 could be strongly bonded. This effect is not sufficiently obtained if only the polyimide layer 3 is laminated or only the Fe—Al-based alloy layer 4 is controlled as explained above. This is obtained the first time when both of them are simultaneously performed. Details of the reason are still being clarified, but it is believed that unlike the conventional layer-state Fe—Al-based alloy layer 4, the Fe—Al-based alloy layer 4 exists in the form of granules which bite into the metal foil 1 and thereby to mitigate stress generated in the multilayer member.

In order to obtain such an effect, in the granular Fe—Al-based alloy at the interface, when an equivalent spherical diameter x (μm) of the maximum grain size thereof is 10 μm or less and the thickness of the Al-containing metal layer or alloy layer 2 on the surface is T (μm), it is required that x and T be in a relationship which is shown by the following formula (1). Note that, as the grain size, a value measured by observing a test piece polished at its cross-section by a scanning type electron microscope or optical microscope is suitably used since the measurement can be carried out with a high precision though it is simple and convenient.

x≦0.5 T (1)

This is due to the fact that if the grain size becomes larger than 10 μm or 0.5 T, the grains may break through the Al-containing metal layer 2 on the surface and the corrosion resistance will fall. Further, the lower limit value of the maximum grain size x of the granular Fe—Al-based alloy is preferably 1.5 μm or more or 0.1 T or more. This is because, when there are only minute particles less than 1.5 μm or less than 0.1 T, the effect of strongly bonding the metal foil 1 and the Al-containing metal layer or alloy layer 2 cannot be obtained. However, when there is a granular allay of 1.5 μm or more or 0.1 T or more, the effect of the present invention can be obtained, therefore there is no problem even if a granular alloy less than 1.5 μm is mixed in.

Further, in the granular Fe—Al-based alloy having a grain size of an equivalent spherical diameter of larger than 1.5 μm, the interval between alloy particles adjacent to each other is further preferably 100 μm or less. This is because if the interval exceeds 100 μm, the function of strongly bonding the metal foil 1 with the Al-containing metal layer or alloy layer 2 is lowered resulting in peeling or breakage of the Al-containing metal layer or alloy layer 2 and fall of the corrosion resistance as well.

Further, the inventors changed the rolling reduction of the metal substrates 5 provided with the Al-containing metal layer or alloy layer 2, thickness of the Al-containing metal layer or alloy layer 2, and so on to prepare granular Fe—Al alloys having different grain sizes and metal substrates 5 provided with the Al-containing metal layers or alloy layers 2 having different intervals and study the adhesiveness between the metal foil 1 and the Al-containing metal layer or alloy layer 2. As a result, when the relationships between the maximum grain size x (μm) of the granular Fe—Al alloy and the intervals y (μm) of them are within ranges represented by the following relational expressions (2) and (3), the adhesiveness between the Al-containing metal layer or alloy layer 2 and the metal foil 1 is high.

0.06<2x/y (2)

x<y (3)

where, x≦10 (μm) and y≦100 (μm).

The size of the granular alloy to which Formula (2) is applied is a range of an equivalent spherical diameter of 1.5 μm or wore. However, in adhesiveness of the Al-containing metal layer or allay layer 2 within this range, there is an optimum range in the interval according to the mean grain size of the granular Fe—Al alloy Qualitatively, when the mean grain size is small, biting into the metal foil 1 becomes small as well. Therefore, desirably the interval among particles is small. When the mean grain size is large, the effect can be expected even when the interval among particles is widened up to about 100 μm.

In an example of the method of production of the polyimide layer-containing flexible substrate according to the present embodiment, the Al-containing metal layer or alloy layer 2 explained above is formed on ordinary steel having a sheet thickness of 200 to 500 μm by hot dip coating, then the steel is rolled by 3 or more passes. At this time, by basically making the rolling reduction lower in the second pass than that in the first pass and making the rolling reduction lower in the third pass than that in the second pass, it is possible to roll down to the final thickness after plating spread over 3 passes or more so as to change the size or state of dispersion of the granular alloy.

More suitably, the thickness of the metal substrate 5 provided with the Al-containing metal layer or allay layer 2 is 200 μm or less from the point of flexibility or 50 μm or more from the point of strength. Further, the thickness of the Al-containing metal layer or alloy layer 2 is preferably 15 to 40 μm from the points of smoothness of outer appearance, oxidation resistance, corrosion resistance, and flexibility as a substrate.

As explained before, it is known fact that in a CIGS solar cell, if diffusion of the metal element, particularly Fe atoms, into the power generation layer occurs, the conversion efficiency is lowered. Particularly, when not glass, but metal is used for the base material, it becomes important to prevent diffusion of Fe atoms. In order to achieve the prevention of diffusion of Fe atoms at a higher level, more preferably the coefficient of thermal expansion in the plane direction of the polyimide layer 3 at 100° C. to 250° C. is 15×10⁻⁶/K or less. This is because permeation and diffusion of the metal composition of the metal foil 1 and Al-containing metal layer or alloy layer 2 into the polyimide layer 3 can be more effectively prevented while keeping bendability. Due to this effect, at the time of production of the solar cell having the configuration which will be explained later, the metal composition described above can be reliably prevented from passing through the polyimide layer 3 and being permeated and diffused into the photovoltaic conversion layer 7 and electrodes 6 and 8 which are formed on the polyimide layer 3.

The reason for the fact that for prevention of permeation and/or diffusion of the metal composition, it is effect that the coefficient of thermal expansion at 100° C. to 250° C. be not more than 15×10⁻⁶/K in the plane direction of the polyimide layer 3 is considered to be as follows. That is, if the coefficient of thermal expansion at 100° C. to 250° C. in the plane direction of the polyimide layer 3 is less than 15×10⁻⁶/K, the orientation in the plane direction of polyimide molecules becomes high (high orientation), and macromolecules regularly oriented by that block the metal and can prevent the metal frau permeation, diffusion, and passing. The inventors engaged in intensive studies and as a result discovered that when the smoothness of the surface of the metal is controlled to the range of an Ra of 20 to 80 inn and an Rz of 150 to 600 nm, a sufficient high adhesiveness between the polyimide molecules and the metal can be secured, therefore it is good. The reason for this is considered to be a good wettability of polyimide molecules upon relief portions on the surface of the metal. However, when the smoothness of the metal surface becomes less than an Ra of 20 nm and an Rz of less than 150 nm in tezmsr ultrathin, the area of the polyimide molecules contacting the metal surface becomes small, therefore a sufficient adhesiveness cannot be obtained. Conversely, when the smoothness of the metal surface exceeds an Ra of 80 nm and exceeds a Rz of 600 nm, the surface phases of the metal surface are too acute, therefore the polyimide molecules cannot sufficiently enter the convex parts on the metal surface and an air layer remains between the polyimide molecules and the bottom portion of the convex parts, so a sufficient adhesiveness cannot be obtained.

As such a polyimide showing a high orientation, the following ones can be exemplified. That is, there can be mentioned a reaction product of a tetracarboxylic acid compound and diamino compound shown in the following chemical formula (1):

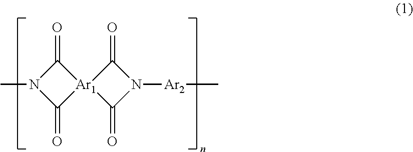

As the tetracarboxylic acid compound containing Ar₁ in Chemical Formula (1), there can be mentioned an aromatic tetracarboxylic acid and its acid anhydride, ester, halide, etc., but an aromatic tetracarboxylic acid compound is preferred. From the point of easy synthesis of the precursor of a polyimide resin of polyamide acid (polyamic acid), its acid anhydride is preferred. Note that, as the aromatic tetracarboxylic acid compound, a compound represented by O(CO)₂Ar₁(CO)₂O can be mentioned as a suitable one. Further, the tetracarboxylic acid compound may be used as one type or as two or more types mixed.

Here, Ar₁ is preferably a tetravalent aromatic group represented by the following chemical formula (2). The sites of substitution of the acid anhydride group [(CO)₂O] may be any sites, but are preferably symmetric. Ar₁ can have a substituent group as well. However, preferably it does not, or, if having one, the group is a C₁ to C₆ lower alkyl group.

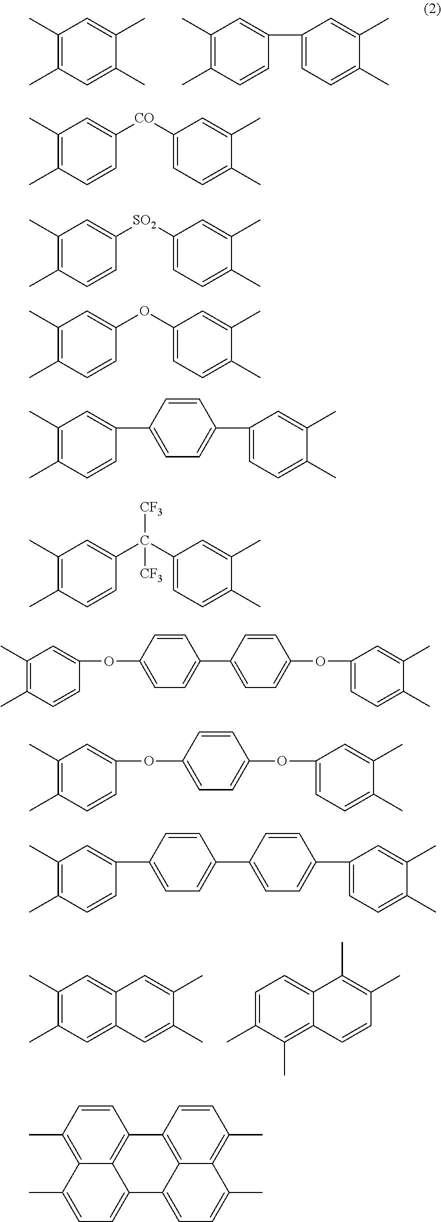

Among these, one selected from among pyromellitic dianhydride (PMDA), 3,3′,4,4′-biphenyl tetracarboxylic acid dianhydride (BPDA), 3,3′4,4′-benzophenone tetracarboxylic acid dianhydride (BTDA), 3,3′4,4′-diphenyl sulfone tetracarboxylic acid dianhydride (DSDA), and 4,4′-oxidiphthalic acid dianhydride (ODPA) is particularly preferably used.

As the diamine compound, an aromatic diamino compound represented by NH₂—Ar₂—NH₂ can be mentioned as a suitable one. Here, AR₂ is preferably selected from among groups represented by the following chemical formula (3). The site of substitution of the amino group may be any site, but the p,p′-site is preferred. Arₑ may also have a substituent group. However, preferably it does not, or, if having one, the group is a C₁ to C₆ lower alkyl group. These aromatic diamino compounds may be used as single types or as two or more types mixed.

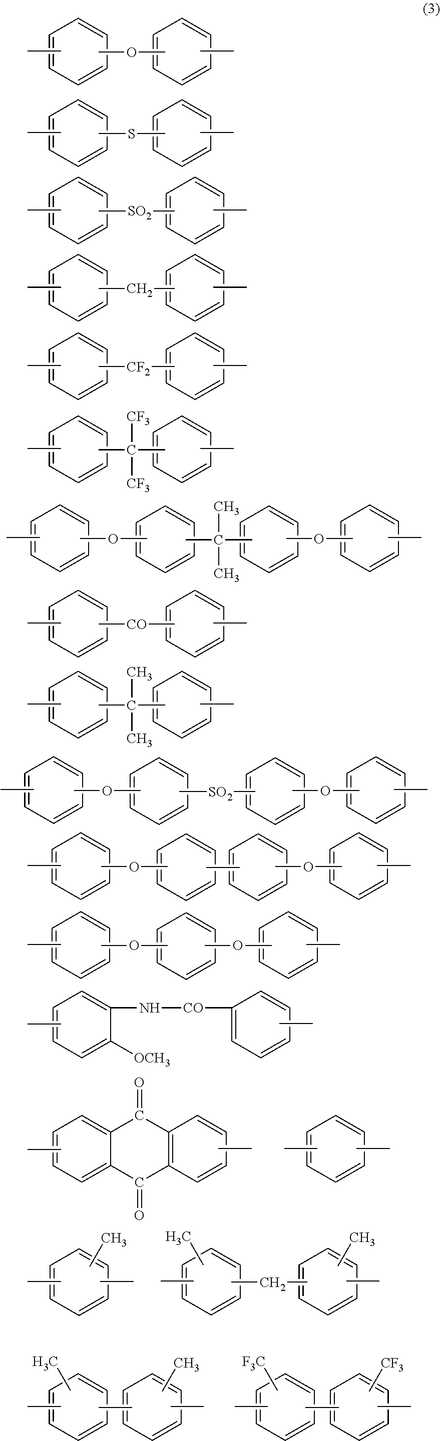

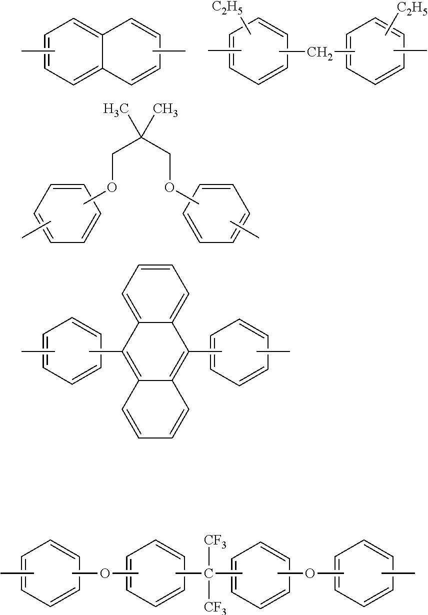

Among these aromatic diamino compounds, diaminodiphenylether (DAPE), 2′-methoxy-4,4′-diaminobenzanilide (MABA), 2,2′-dimethyl-4,4′-diaminobiphenyl (m-TB), paraphenylenediamine (P-PDA), 1,3-bis(4-aminophenoxy)benzene (TPE-R), 1,3-bis(3-aminophenoxy)benzene (APB), 1,4-bis(4-aminophenoxy)benzene (TPE-Q), and 2,2-bis[4-(4-aminophenoxy)phenyl]propane (BAPP) may be mentioned as preferable ones.

Note that, in the aromatic diamino compound, part or all of its amino groups may be trialkylsilylated or may be amidated by acetic acid or another such aliphatic acid.

A polyimide obtained by reaction of an aromatic tetracarboxylic acid having Ar₁ represented by Chemical Formula (2) and an aromatic diamino compound having Ar₂ represented by Chemical Formula (3) is preferred. Further, there is a difference in a potential of manifesting high orientation according to the structure of the polyimide. If it has structural features as follows, it tends to further easily bring about high orientation for that polyimide.

(a) It forms a polyimide having a rigid straight-chain structure.
(b) It does not have a structure having a large degree of freedom in revolution such as ether bond or methylene bond.
(c) It has an amide group estimated to have an action reducing the coefficient of thermal expansion.

By providing the above features, it is possible to obtain a polyimide having a glass transition point temperature of 300 to 450° C. Further, when forming a polyimide layer, by controlling a curing temperature, the coefficient of thermal expansion at 100° C. to 250° C. in the plane direction of the polyimide layer 3 can be controlled to 15×10⁻⁶/K or less.

Next, in the case where the polyimide layer 3 according to the present embodiment is formed, the method of forming this will be explained.

In a solvent, the above tetracarboxylic acid dianhydride and diamino compound are mixed in an almost equimolar ratio and are reacted within a range of reaction temperature from 0 to 200° C., preferably within a range from 0 to 100° C., to thereby synthesize the precursor of polyimide of polyamide acid (polyamic acid). Next, a method of obtaining a polyimide by imidizing this will be exemplified.

As the solvent, there can be mentioned N-methylpyrrolidone (NMP), dimethylformamide (DMF), dimethylacetamide (DMac), dimethyl sulfoxide (DMSO), dimethyl sulfate, sulfolane, butyrolactone, cresol, phenol, halogenated phenols, cyclohexanone, dioxane, tetrahydrofuran, diglyme, triglyme, and so on.

Note that, when forming the polyimide layer 3 on the Al-containing metal layer or alloy layer 2, it is possible to perform the process up to synthesis of the polyamide acid in a reaction vessel, coat the polyamide acid (or polyamide acid solution) on the Al-containing metal layer or alloy layer 2, then imidize it to form the polyimide layer 3. Alternatively, it is possible to perform the process up to imidization in the reaction vessel, coat the polyimide solution on the Al-containing metal layer or alloy layer 2, and remove the solvent by drying to thereby form the polyimide layer 3.

Further, as explained above, the coefficient of thermal expansion at 100° C. to 250° C. in the plane direction of the polyimide layer 3 is preferably not more than 15×10⁻⁶/K. This can be realized by controlling the orientation of molecules in the polyimide layer. Specifically, by forming the polyimide layer while controlling the temperature as follows, a polyimide layer having a high orientation in which the coefficient of thermal expansion at 100° C. to 250° C. in the plane direction of the polyimide layer 3 is 15×10⁻⁶/K or less can be formed.

That is, when volatilizing the solvent from the polyamide acid solution containing a solvent coated on the base material and curing it by drying, control is carried out so that the solvent gradually volatilizes so that the polyimide molecules becomes arranged as regularly as possible in a temperature zone of 100 to 150° C. in which imidization starts. By preventing the structure of the polyimide from being disturbed in this way, a polyimide layer in which the coefficient of thermal expansion at 100° C. to 250° C. in the plane direction of the polyimide layer 3 is 15×10⁻⁶/K or less can be obtained. Preferably, an initial condition of heat treatment is that a cumulative time of the temperature at 100 to 150° C. is 3 minutes or more, more preferably a cumulative time of the temperature at 110 to 140° C. is 5 minutes or more.

The polyimide layer 3 formed on the metal substrate 5 in the present invention is preferably one where in the form of the polyimide layer-containing flexible substrate 10, the surface roughness of the polyimide layer surface which is positioned on the outside (side which does not contact the metal substrate 5) is preferably 10 nm or less in measurement according to AFM (Atomic Force Microscope), more preferably 5 nm or less. If the surface roughness exceeds this value, in the case configuring a solar cell, defects will easily occur in the bottom electrode and photovoltaic conversion layer. In order to make the surface roughness of the polyimide surface 10 nm or less, when forming the polyimide layer 3 on the metal substrate 5, it is possible to coat the polyamide acid solution in a solution state then dry and imidize it to make the value lower.

Further, the range of the coefficient of thermal expansion at 100° C. to 250° C. in the plane direction of the polyimide layer 3 is also influenced by the structures of the monomer ingredients of the acid and diamine which compose the polyimide. From such a viewpoint, there can be mentioned a polyimide which does not have a structure with a large degree of freedom in revolution such as an ether bond or methylene bond, but has a rigid straight-chain structure. This polyimide has the feature that the glass transition point temperature is high and is within a range of 300 to 450° C.

When applying the polyimide layer-containing flexible substrate 10 exemplified by the embodiment described above to the substrate for a flexible solar cell, the thickness of the polyimide layer 3 must be 1.5 μm or more and is preferably 2 μm or more, more preferably 3 μm or more. This is because the effect of the polyimide layer 3 as the protective film becomes high, and the permeation of the metal composition forming the metal foil 1 and Al-containing metal layer or alloy layer 2 into the photovoltaic conversion layer which is formed on the polyimide layer 3 can be reliably prevented. From the viewpoint of securing flexibility, the thickness of the polyimide layer is 100 μm or less, preferably 50 μm or less.

Note that, in the present invention, the Al-containing metal layer or alloy layer 2 of the metal substrate 5 or the surface thereof can be treated by chemical or physical surface treatment to thereby treat the surface of the metal substrate or any layer may be interposed between the metal substrate 5 and the polyimide layer 3 within a range that does not obstruct the effect of the present invention.

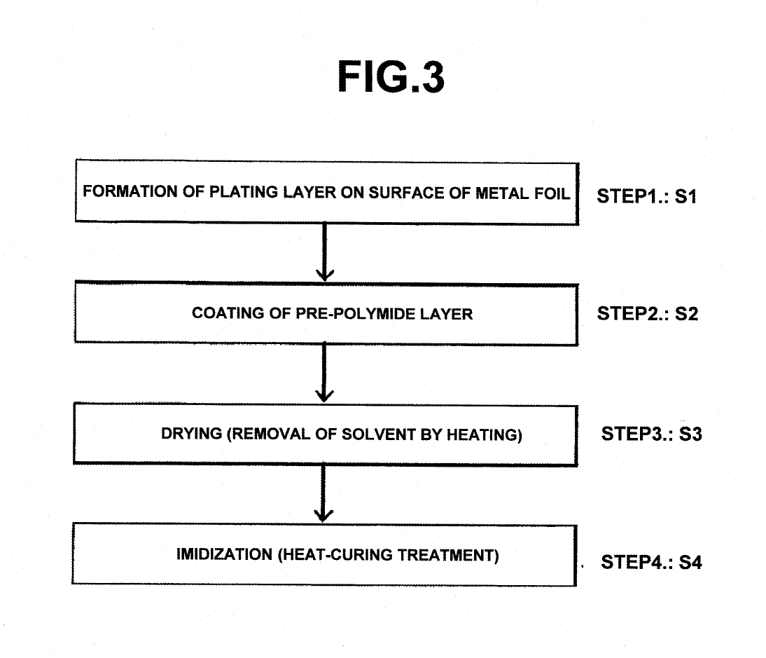

Next, the method of production of the polyimide layer-containing flexible substrate 10 in the present embodiment will be explained in detail with reference to FIG. 3. First, on the surface of the metal foil 1, a metal layer or alloy layer 2 made of copper, nickel, zinc, or aluminum or an alloy of the same is formed by for example plating (S1). As the metal foil 1, for example, a metal foil made of ordinary steel or SUS is used. As the plating method, for example, the hot dip coating method explained above may be employed. Here, in the method of production of the polyimide layer-containing flexible substrate 10 according to the first embodiment, the process of forming the metal layer or alloy layer 2 is unnecessary.

Subsequently, a precursor of polyimide of the method of synthesis explained above of a polyamide acid solution or a polyimide solution is coated on the metal layer or alloy layer 2 (S2). In the method of production of the polyimide layer-containing flexible substrate 10 according to the first embodiment, it is formed on the metal foil. Here, the polyamide acid solution and polyimide solution will be sometimes referred to all together as a “pre-polyimide layer”. After coating the pre-polyimide layer, by drying [removal of solvent by heating] (S3) and imidization [heat-curing treatment] (S4), a polyimide layer 3 bonded to the metal layer or alloy layer 2 is formed. In the method of production of the polyimide layer-containing flexible substrate 10 according to the first embodiment, a polyimide layer 3 bonded onto the metal foil is formed. Note that, when coating the polyimide solution, it has been already imidized, therefore step 4 (S4) is not executed.

When using a polyimide solution as the pre-polyimide layer, at step 3 (S3), the temperature at for example 100 to 250° C. is maintained for a cumulative time of 1 to 10 minutes by temperature control so as to dry the layer (removal of solvent by heating) whereby a polyimide film having a high orientation in the plane direction is formed. When using a polyamide acid, at step 4 (S4), for example, by imidization by controlling the temperature so that a temperature at 100 to 150° C. is maintained for a cumulative time of 3 to 15 minutes, preferably a temperature at 110 to 140° C. is maintained for a cumulative time of 5 to 10 minutes, or a temperature at 320 to 380° C. is maintained for a cumulative time of 5 minutes or more, preferably 5 to 60 minutes, a polyimide film having a high orientation in the plane direction is formed.

According to the above process, a polyimide layer-containing flexible substrate 10 in which a polyimide layer 3 having a high orientation in the plane direction is formed is produced. In the above, a method of forming the polyimide layer 3 according to a so-called “cast method” of coating a polyamide acid solution was explained, but the method of formation of the polyimide layer 3 is not limited so far as the polyimide layer 3 satisfies the predetermined requirements. There can be mentioned a method of hot press bonding a polyimide film which is formed into a film through or not through an adhesive or a method of forming a polyimide layer according to a vapor deposition process. Note, in order to simply control the thickness of the polyimide layer 3 and keep the surface roughness of the polyimide layer 3 low, the cast method is the most suitable.

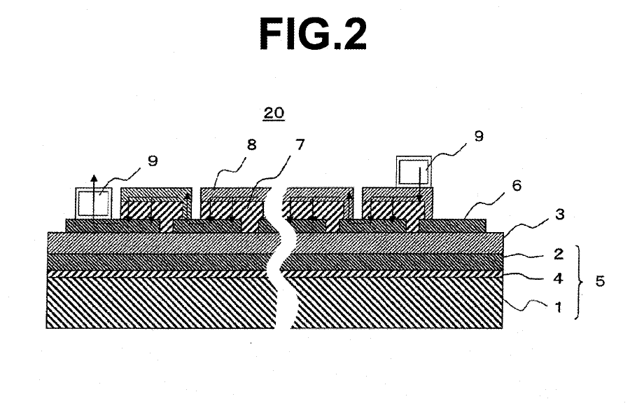

Next, an embodiment of a flexible solar cell 20 in the present invention will be explained by using FIG. 2. The flexible solar cell in the present embodiment is formed by using the polyimide layer-containing flexible substrate 10 explained according to FIG. 1. An example of that is a structure in which, as shown in FIG. 2, a bottom electrode (back electrode) 6 is provided on the polyimide layer 3 (insulating layer) of the polyimide layer-containing flexible substrate 10, a photovoltaic conversion layer (light-absorbing layer) 7 is provided on the bottom electrode 6, a transparent electrode (upper electrode) 8 is provided on the photovoltaic conversion layer 7, and extraction electrodes 9 which are connected to the bottom electrode 6 and transparent electrode 8 are provided. Note that, although not shown, antireflection coatings etc. may be further provided as well.

The bottom electrode 6 is not particularly limited so far has it is made of a material having conductivity. For example, metal, semiconductor, or the like having a volume resistivity not more than 6×10⁶ Ω·cm can be used. Specifically, for example molybdenum can be used. Note that, the thickness of the bottom electrode 6 is preferably 0.1 to 1 μm in the point of flexibility.

The photovoltaic conversion layer 7 is preferably one having a good light absorption, that is, a large optical-absorption coefficient, in order to obtain a high power generation efficiency. As the photovoltaic conversion layer of the flexible solar cell in the present invention, a compound semiconductor is preferred. A Group compound called chalcopyrite made of Cu, In, Ga, Al, Se, S, or the like is used. For example, there can be mentioned CdS/CdTe, CIS[CuInS₂], CIGS[Cu(In,Ga)Se₂], CIGSS[Cu(In,Ga)(Se,S)₂], SiGe, CdSe, GaAs, GaN, InP, etc. The thickness of the photovoltaic conversion layer 7 is preferably 0.1 to 4 μm from the viewpoint of achievement of both power generation efficiency and flexibility.

The transparent electrode 8 is an electrode on the light incident side, therefore a material having a high degree of transparency is used so that the light can be efficiently concentrated. For example, an aluminum-doped zinc oxide (ZnO) or indium tin oxide (ITO) is used. The thickness of the transparent electrode 8 is 0.1 to 0.3 μm from the viewpoint of flexibility. Note that, in order to prevent loss of the incident light due to reflection etc., an antireflection film may be formed in contact with the transparent electrode 8 as well.

As the extraction electrodes 9, for example, Ni, Al, Ag, Au, NiCr, or other metal and alloy can be used as the material.

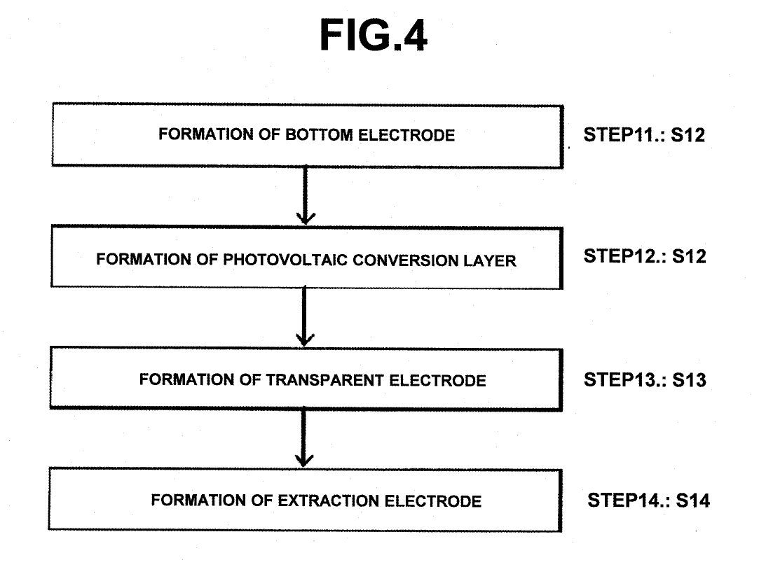

Subsequently, a schematic method of production of the flexible solar cell according to the present embodiment will be explained by FIG. 4. First, on the polyimide layer 3 of the polyimide layer-containing flexible substrate 10, an electrode material, for example, molybdenum, is laminated to form a bottom electrode 6 (S11). Specifically, molybdenum is laminated on the polyimide layer 3 by a sputtering method or vapor deposition method.

After formation of the bottom electrode 6, any of the above compound semiconductors is laminated on that to form a photovoltaic conversion layer 7 (S12). Specifically, a compound semiconductor material is laminated on the bottom electrode 6 according to any process among sintering, chemical deposition, sputtering, close space sublimation multi-elemental deposition method, and selenization.

When forming a CdS/CdTe film as the photovoltaic conversion layer 7, a method of coating a CdS paste and CdTe paste in order and sintering at 600° C. or less to form a thin film can be exemplified. Further, in place of this method, a method of forming a CdS film by chemical deposition or sputtering or the like and then forming a CdTe film by close space sublimation can be employed as well.

When forming a CIS[CuInS₂] film, CIGS[Cu(In,Ga)Se₂] film, or CIGSS[Cu(In,Ga)(Se,S)₂] film as the photovoltaic conversion layer 7, these compounds are formed into a paste and coated on the polyimide layer 3 and sintered at 350 to 550° C. to thereby form a photovoltaic conversion layer 7 based on these compounds.

When forming the compound semiconductor-based photovoltaic conversion layer 7 as described above, zinc (Zn) may be introduced into the compound semiconductor film as well. As the method of introduction, for example, a method of coating an aqueous solution of zinc sulfate, zinc chloride, zinc iodide, etc. on the compound semiconductor film can be used. Alternatively, a multilayer member in which the process of formation up to the photovoltaic conversion layer 7 is carried out may be dipped in these aqueous solutions as well. By mixing zinc, the photovoltaic conversion efficiency can be improved.

After formation of the photovoltaic conversion layer 7, a transparent electrode 8 made of an aluminum-doped zinc oxide (ZnO) or indium tin oxide (ITO) is laminated on that by the sputtering method or the like (S13). After that, extraction electrodes 9 are formed by connection to the bottom electrode 6 and transparent electrode 8 (S14). As the material of the extraction electrode, aluminum or nickel can be used.

Note that, an alkali metal supplying layer may be formed between the polyimide layer 3 and the bottom electrode 6 as well. By permeation and/or diffusion of a portion of the alkali metal into the photovoltaic conversion layer from the alkali metal supplying layer, an effect of improvement of the photovoltaic conversion efficiency can be expected.

### EXAMPLES

Below, examples will be used to explain the embodiments of the present invention more specifically. Further, comparative examples will be show to clarify the superiority of the present embodiments.

### 1. Metal Substrate Provided with Al-Containing Metal Layer or Alloy Layer

As the metal substrate provided with an Al-containing metal layer or alloy layer which becomes the substrate part of the polyimide layer-containing flexible substrate, an aluminum-plated steel foil having a film thickness of 150 μm was used. This aluminum-plated steel foil is prepared according to Embodiment 1 described above and is comprising 100 μm steel foil on the two surfaces of which 25 μm aluminum layers are provided. Further, the principal ingredients other than iron of the used material steel are as shown in Table 1.

TABLE 1
Principal Ingredients Other than Iron of Material Steel

| Element | C | Si | Mn | P | S | Ti | Mb | Al | B | N |
|---|---|---|---|---|---|---|---|---|---|---|
| Content | 0.0022 | 0.08 | 0.31 | 0.008 | 0.010 | 0.033 | 0.001 | 0.05 | 0.0005 | 0.0031 |
| (wt %) | | | | | | | | | | |

### 2 Measurement of Various Physical Properties and Methods of Performance Tests

Coefficient of Thermal Expansion (CTE)

The coefficient of thermal expansion in the plane direction of the polyimide formed on the metal substrate provided with an Al-containing metal layer or alloy layer was measured by using a thermomechanical analyzer/SS6100 (made by Seiko Instrument Inc.) as follows. A polyimide layer was formed on a metal foil provided with an Al-containing metal layer, then the metal foil was removed by etching to form a film-state polyimide. The temperature was elevated at a temperature elevation rate of 10° C./min up to 260° C. under a load of 5 g. After that, this was cooled up to a room temperature at 5° C./min., then the coefficient of thermal expansion at 100° C. to 250° C. was calculated from the dimensional change in the plane direction of the polyimide film at the time of temperature fall. Further, as the coefficient of thermal expansion in the plane direction of the metal substrate, the coefficient of thermal expansion was calculated by the same method as that described above except for use of a metal substrate in place of the polyimide formed in a film state as described above.

Measurement of Glass Transition Point Temperature

The glass transition point temperature of polyimide was measured by using a viscoelastic analyzer RSA-II (made by Rheometric Science Effie Ltd.) as follows. A polyimide layer as formed on a metal foil provided with an Al-containing metal layer, then the metal foil was removed by etching to form a film-state polyimide. This was cut to a 10 sin width. This was given vibration of 1 Hz while raising the temperature from room temperature to 400° C. at a rate of 10° C./min. The maximum value of the loss tangent (Tan δ) at this time was defined as the glass transition point temperature.

Measurement of Surface Roughness of Polyimide Layer

The outside surface layer of the polyimide layer formed on the metal substrate was observed using an atomic force microscope (AFM) [Multi Mode 8] made by Bruker Corporation in a tapping mode by. A 10 μm square field was examined five times and the mean value thereof was determined as the value of surface roughness. The surface roughness (Ra) represents the arithmetic mean roughness (JIS B 0601-1994).

Detection of Metal Configuring Metal Substrate Provided with Al-Containing Metal Layer or Alloy Layer

Present/absence of contamination (diffusion) of the metal configuring the metal substrate provided with the Al-containing metal layer or alloy layer into the polyimide layer and photovoltaic conversion layer was measured as follows. As the detection device, a Glow Discharge Light Spectrum Analyzer GD-PROFILER2 (made by HORIBA, Ltd. (made by HORIBA JOBIN YVON SAS)) was used. The present device was used to detect the light intensity for each wavelength corresponding to the target metal element (Al, Fe, Si, or the like) for the polyimide layer and photovoltaic conversion layer to prepare an emission spectrum and the peak intensity of the peak corresponding to the metal was measured from that spectrum. From the obtained peak intensity, the content (amount of contamination) of the target metal element is found as follows.

(1) For each target metal element, two or more types of known concentration standard samples are prepared.

(2) For each target metal element, the peak intensity of the emission spectrum of the standard sample having each concentration is measured, and a calibration curve (output voltage (V)-concentration (wt %)) for conversion of the metal element concentration is prepared.

(3) For each sample taken from the polyimide layer and photovoltaic conversion layer, spectroscopic analysis is carried out and the peak intensity of the emission spectrum is measured.

(4) The peak intensity of the emission spectrum of each metal element is detected by the output voltage (V) of the detector, therefore the concentration (mass percentage) of the metal element is read from the calibration curve prepared in (2).

(5) A case where the concentration is less than 0.1 wt % is evaluated as less than the detection limit.

### 3. Synthesis of Polyamide Acid (Polyimide Precursor) Solution

### Synthesis Example 1

A reaction vessel which is provided with a thermocouple and stirrer and can be charged with nitrogen was charged with N,N-dimethylacetamide. Into this reaction vessel, 2,2′-dimethyl-4,4′-diaminobiphenyl (m-TB) was charged. Next, 3,3′,4,4′-biphenyl tetracarboxylic acid dianhydride (BPDA) and pyromellitic dianhydride (PIMA) were added. The materials were charged so that the total amount of charging of monomers was 15 wt % and the molar ratio of the acid anhydrides (BPDA:PMDA) became 20:80. After that, the mixture continued to be stirred for 3 hours to thereby obtain a resin solution of polyamide acid “a”. The solution viscosity of this polyamide acid “a” was 20,000 mPa·s. Note that, the solution viscosity is the value of apparent viscosity at 25° C. by an E type viscometer (same below).

### Synthesis Example 2

A reaction vessel which is provided with a thermocouple and stirrer and can be charged with nitrogen was charged with an N,N-dimethylacetamide. Into this reaction vessel, 2,2-bis[4-(4-aminophenoxy)phenyl]propane (BAPP) was charged and stirred in the vessel while dissolving it. Next, pyromellitic dianhydride (PMDA) was added. The materials were charged so that the total amount of charging of monomers was 15 wt %. After that, the mixture continued to be stirred for 3 hours to thereby obtain a resin solution of polyamide acid “b”. The solution viscosity of this polyimide acid “b” was 3,000 mPa·s.

### Synthesis Example 3

A reaction vessel which is provided with a thermocouple and stirrer and can be charged with nitrogen was charged with an N,N-dimethylacetamide. Into this reaction vessel, 4,4-diaminodiphenylether (4,4-DAPE) was charged and stirred in the vessel while dissolving it. Next, benzophenone tetracarboxylic acid dianhydride (BTDA) was added. The materials were charged so that the total amount of charging of monomers was 15 wt %. After that, the mixture continued to be stirred for 3 hours to thereby obtain a resin solution of polyamide acid “c”. The solution viscosity of this polyamide acid “c” was 3,000 mPa·s.

### 4. Evaluation of Performance

### Example 1

A metal substrate provided with the Al-containing metal layer described above constituted by an aluminum-plated steel foil having a film thickness of 150 μm (metal substrate in which an aluminum layer was formed on a metal foil of ordinary steel by plating) was prepared. The polyamide acid solution “a” prepared in the above Synthesis Example 1 was coated on this foil, dried, and heated under conditions of a temperature of 110 to 140° C. for a emulative time of 5 minutes and a temperature of 320 to 380° C. for a cumulative time of 5 minutes or more to cure it and thereby form a polyimide layer having a film thickness of 3 μm. In the polyimide layer-containing flexible substrate provided with the polyimide layer on the surface of the metal substrate provided with the Al-containing metal layer obtained in this way, the Tg of the polyimide layer was 360° C., the coefficient of thermal expansion in the plane direction was 6×10⁻⁶/K, and the surface roughness of the polyimide layer surface was 2.5 inn.

On this polyimide layer-containing flexible substrate, a molybdenum (Mo) film was formed to a thickness of 1 μm as the bottom electrode by the vapor deposition method. Next, by the vapor deposition method, a Cu(In,Ga)Se₂ film (thickness: 2 μm) was formed on the Mo film as a p-type semiconductor layer to thereby form a multilayer member having a bottom electrode (back electrode) on the polyimide layer-containing flexible substrate and having a p-type semiconductor layer on that.

Next, an aqueous solution of zinc sulfate (ZnSO₄) (concentration of Zn²⁺ was 0.025 mol/L) was prepared, the aqueous solution was kept at 85° C. in a thermostatic bath, and the multilayer member was dipped for about 3 minutes. After that, the multilayer member was washed by pure water and further heat treated at 400° C. for 10 minutes in a nitrogen atmosphere.

Subsequently, by dual sputtering using a zinc oxide (ZnO) target and magnesium oxide (MgO) target, a Zn_{0.9}.Mg_{0.1}O film (thickness: 100 nm) was formed as an n-type semiconductor layer on the p-type semiconductor of the multilayer member. At this time, in an argon gas atmosphere (gas pressure: 2.66 Pa (2×10⁻² Torr)), sputtering was carried out by applying a high frequency having a power of 200 W to the ZnO target and applying a high frequency having a power of 120 W to the MgO target. A photovoltaic conversion layer was formed on the bottom electrode in this way.

Next, using the sputtering method, a conductive film having translucency of an ITO film (thickness: 100 nm) was formed on the photovoltaic conversion layer as a transparent electrode (upper electrode). The ITO film was formed by applying a high frequency having a power of 400 W to the target in an argon gas atmosphere (gas pressure: 1.07 Pa (8×10⁻³ Torr)).

Finally, an NiCr film and an Ag film were laminated on the bottom electrode (Mo) and on the transparent electrode (ITO film) by using the electron beam vapor deposition method to thereby form the extraction electrode and prepare a flexible solar cell. When analyzing the metal ingredients in the polyimide layer and photovoltaic conversion layer of the prepared flexible solar cell according to the above emission spectrum method, contamination of metal due to diffusion was not confirmed in any case.

### Example 2

A metal substrate provided with an Al-containing metal layer (aluminum-plated steel foil) the same as that in Example 1 and polyamide acid solution “a” were used and heated under conditions of a temperature of 110 to 140° C. for a cumulative time of 3 minutes and a temperature of 320 to 380° C. for a cumulative time of 5 minutes or more to cure it and thereby form a polyimide layer having a film thickness of 3 μm. The Tg of the formed polyimide layer was 360° C., the coefficient of thermal expansion in the plane direction was 15×10⁻⁶/K, and the surface roughness of the polyimide layer surface was 2.1 nm. After that, when a flexible solar cell was formed in the same way as Example 1 and the metal ingredients in the polyimide layer and photovoltaic conversion layer were analyzed, contamination of metal due to diffusion was not confirmed in any case.

### Example 3

A metal substrate provided with an Al-containing metal layer (aluminum-plated steel foil) the same as that in Example 1 and polyamide acid solution “a” were used and heated under conditions of a temperature of 110 to 140° C. for a cumulative time of 1 minute and a temperature of 320 to 380° C. for a cumulative time of 5 minutes or more to cure it and thereby form a polyimide layer having a film thickness of 3 μm. The Tg of the formed polyimide layer was 360° C., the coefficient of thermal expansion in the plane direction was 33×10⁻⁶/K, and the surface roughness of the polyimide layer surface was 3.9 nm. After that, when a flexible solar cell was formed in the same way as Example 1 and the metal ingredients in the polyimide layer were analyzed, contamination of Fe and Al into the polyimide layer due to diffusion was confirmed. However, contamination by than was not confirmed in the photovoltaic conversion layer.

### Example 4

On a metal substrate provided with an Al-containing metal layer (aluminum-plated steel foil) the same as that in Example 1, the polyamide acid solution “b” prepared in the above Synthesis Example 2 was coated. This was dried and heated under conditions of a temperature of 110 to 140° C. for a cumulative time of 5 minutes and a temperature of 320 to 380° C. for a emulative time of 5 minutes or more to cure it and thereby form a polyimide layer having a film thickness of 3 μm. The Tg of the formed polyimide layer was 300° C., the coefficient of thermal expansion in the plane direction was 50×10⁻⁶/K, and the surface roughness of the polyimide layer surface was 2.2 nm. After that, when a flexible solar cell was formed in the same way as Example 1 and the metal ingredients in the polyimide layer were analyzed, contamination of Fe and Al into the polyimide layer due to diffusion was confirmed. However, contamination by than was not confirmed in the photovoltaic conversion layer.

### Comparative Example 1

A metal substrate provided with an Al-containing metal layer (aluminum-plated steel foil) the same as that in Example 1 and a polyamide acid solution “a” were used. While changing the thickness of coating of the polyamide acid solution “a” so that the film thickness after imidization became the following thickness, these were heated under conditions of a temperature of 110 to 140° C. for a cumulative time of 1 minute and a temperature of 320 to 380° C. for a cumulative time of 5 minutes or more to cure it and thereby form a polyimide layer having a film thickness of 1 μm. The Tg of the formed polyimide layer was 360° C., the coefficient of thermal expansion in the plane direction was 34×10⁻⁶/K, and the surface roughness of the polyimide layer surface was 3.2 nm. After that, when a flexible solar cell was formed in the same way as Example 1 and the metal value in the polyimide layer was analyzed, contamination of Fe and Al into the polyimide layer due to diffusion was confirmed. Further, it was confirmed that Fe and Al passed through the polyimide layer and were diffused and mixed into the photovoltaic conversion layer as well.

### Comparative Example 2

On a metal substrate provided with an Al-containing metal layer (aluminum-plated steel foil) the same as that in Example 1, the polyamide acid solution “b” prepared in the above Synthesis Example 2 was coated so that the film thickness after imidization became the following thickness. This was dried and heated under conditions of a temperature of 110 to 140° C. for a cumulative time of 5 minutes and a temperature of 320 to 380° C. for a cumulative time of 5 minutes or more to cure it and thereby form a polyimide layer having a film thickness of 1 μm. The Tg of the formed polyimide layer was 300° C., the coefficient of thermal expansion in the plane direction was 50×10⁻⁶/K, and the surface roughness of the polyimide layer surface was 4.1 nm. After that, when a flexible solar cell was formed in the same way as Example 1 and the metal ingredients in the polyimide layer were analyzed, contamination of Fe and Al into the polyimide layer due to diffusion was confirmed. Further, it was confirmed that Fe and Al passed through the polyimide layer and were diffused and mixed into the photovoltaic conversion layer as well.

### Comparative Example 3

On a metal substrate provided with an Al-containing metal layer (aluminum-plated steel foil) the same as that in Example 1, the polyamide acid solution “c” prepared in the above Synthesis Example 3 was coated. This was dried and heated under conditions of a temperature of 110 to 140° C. for a cumulative time of 5 minutes and a temperature of 320 to 380° C. for a cumulative time of 5 minutes or more to cure it and thereby form a polyimide layer having a film thickness of 3 μm. The Tg of the formed polyimide layer was 280° C., the coefficient of thermal expansion in the plane direction was 55×10⁻⁶/K, and the surface roughness of the polyimide layer surface was 2.8 nm. After that, when a flexible solar cell was formed in the same way as Example 1 and the metal ingredients in the polyimide layer were analyzed, contamination of Fe and Al into the polyimide layer due to diffusion was confirmed. Further, it was confirmed that Fe and Al passed through the polyimide layer and were diffused and mixed into the photovoltaic conversion layer as well.

As apparent from the results shown in Table 2, in Examples 1 to 4 forming polyimide layers having thicknesses exceeding 1.5 μm and having Tg's not less than 300° C., contamination of metal into the photovoltaic conversion layer due to diffusion was not confirmed. Further, in addition to this, it was confirmed that the polyimide layer controlled so that the coefficient of thermal expansion in the plane direction became 15×10⁻⁶/K or more was excellent in suppression of contamination of metal into the polyimide layer as well. Accordingly, the flexible solar cell of the present invention using the polyimide layer-containing flexible substrate of the present invention provides good features.

TABLE 2

| | Polyimide layer (insulating layer) | | | Contamination by metal | | |
|---|---|---|---|---|---|---|
| | Tg | Film thickness | Thermal expansion | In | In photovoltaic | |
| | (° C.) | (μm) | coefficient (1/K) | resin | conversion layer | Evaluation |
| Ex. 1 | 360 | 3 | 6 × 10⁻⁶ | No | No | Good |
| Ex. 2 | 360 | 3 | 15 × 10⁻⁶ | No | No | Good |
| Ex. 3 | 360 | 3 | 33 × 10⁻⁶ | Yes | No | Good |
| Ex. 4 | 300 | 3 | 50 × 10⁻⁶ | Yes | No | Good |
| Comp. Ex. 1 | 360 | 1 | 34 × 10⁻⁶ | Yes | Yes | Poor |
| Comp. Ex. 2 | 300 | 1 | 50 × 10⁻⁶ | Yes | Yes | Poor |
| Comp. Ex. 3 | 280 | 3 | 55 × 10⁻⁶ | Yes | Yes | Poor |

(Note)
Contamination by metal: Yes: target metal is detected by emission spectrum detection method No: target metal is less than detection limit by emission spectrum detection method

### 5. Evaluation of Adhesiveness of Al-Containing Metal Layer in Metal Substrate Provided with Al-Containing Metal Layer (Indicator of Elastic Plastic Deformation Property) and Evaluation of Corrosion Resistance

The above various types of foils and metal substrates provided with Al-containing metal layers produced according to Embodiments 1 and 2 and the prior art were evaluated for adhesiveness between the Al-containing metal layer and the metal foil according to the following method.

The metal substrate provided with the Al-containing metal layer in Embodiment 1 was produced as follows. As a first rolling treatment, ultra low carbon steel was hot-rolled and cold-rolled to form a rolled steel sheet having a thickness of 300 μm. A pure Cu pre-plating film was formed on this rolled steel sheet by electroplating as the pre-plating. Using a copper sulfate bath as the plating bath for the electrolytic Cu plating, the rolled steel sheet after pre-plating was dipped in the Al-containing metal kept at 660° C. for 20 seconds as plating to thereby perform hot dip coating by Al. Further, as a second rolling treatment, the rolled steel sheet after plating was rolled with a rolling reduction of 10 to 20% for each pass to thereby to produce a metal substrate provided with an Al-containing metal layer having a sheet thickness of 30 μm.

The metal substrate provided with the Al-containing metal layer in Embodiment 2 was produced in the following way. Hot dip coating by Al was carried out on soft steel having a sheet thickness of 300 μm. After that, this was rolled by seven passes until the thickness of the steel layer became 30 μm to form many foils. The rolling reduction in the second pass was made larger that in the first pass and the rolling reduction was lowered in the third pass to thereby control the dispersion state of the granular alloys in the production.

In the metal substrate provided with the Al-containing metal layer in Embodiment 1 produced in this way, the Vicker's hardness was within a range of 500 to 600 Hv, and the metal substrate provided with the Al-containing metal layer in Embodiment 2 satisfied the above numerical formulas (1) to (3).

### Examples 5 to 14

Further, as another embodiment, two types of ordinary steels having a thickness of 0.3 mm and having different surface smoothnesses, two types of SUS430 (SUS) having different surface smoothnesses, Ni-plated steel obtained by electrolytic Ni plating on ordinary steel, Zn-plated steel obtained by electrolytic zinc plating on ordinary steel, and Cu-plated steel obtained by electrolytic copper plating on ordinary steel were prepared, then were rolled by seven passes until the thickness became 30 μm to thereby obtain two types of ordinary steel foils having different surface smoothnesses (Examples 5 and 13), two types of SUS foils having different surface smoothnesses (Examples 6 and 14), a metal substrate provided with an Ni-containing metal layer (Ni-plated steel foil, Example 7), a metal substrate provided with a Zn-containing metal layer (Zn-plated steel foil, Example), and a metal substrate provided with a Cu-containing metal layer (Cu-plated steel foil, Example 9). The smoothnesses (Ra (nm)) of surfaces of these metal substrates, the metal substrate provided with the Al-containing metal layer according to Embodiment 1 (Al-plated steel foil, Example 10), the metal substrate provided with the Al-containing metal layer of Embodiment 2 (Al-plated steel foil, Example 11), and a metal substrate provided with an Al-containing metal layer which was produced in the prior art and had a film thickness of 30 μm (Al-plated steel foil, Vicker's hardness of about 900 Hv, Example 12) will be shown in Table 3. Further, under the same conditions as the above description of measurement of various physical properties and methods of performance tests, the coefficients of thermal expansions of the metal substrates in Examples 5 to 14 were measured. The results re shown in Table 3.

On the metal substrates in Examples 5 to 14, a polyimide layer according to the present embodiment was formed according to Example 1 to prepare polyimide layer-containing flexible substrates according to Examples 5 to 14.

These polyimide layer-containing flexible substrates in Examples 5 to 14 were subjected to peel tests to confirm the adhesiveness of the metal layers (metal plating layers). Note that, a peel test attached a commercially available adhesive tape to the surface of the polyimide layer, pressed it from the top by a force of 5 kg, then peeled off the tape and observed the tape by a microscope to evaluate if the metal of the plating layer was transferred to and deposited onto the tape. The test was carried out 10 times. The case where a number of times of deposition of metal was 0 was evaluated as “very good”, the case where the number of times was 1 to 2 was evaluated as “good”, the case where the number of times was 3 to 5 was evaluated as “fair”, the case where the number of times was 6 to 8 was evaluated as “barely fair”, and the case where the number of times was 9 or more was evaluated as “poor”. Further, the same test was continued for a test piece which was evaluated as “very good”. The case where the number of times of deposition of metal was 0 even when the test was carried out 30 times was evaluated as “very very good”. Further, the interfaces where peeling occurred in the case where peeling occurred will be shown in Table 3.

From Table 3, it is learned that the polyimide layer-containing flexible substrates using ordinary steel foil (Example 5), SUS foil (Example 6), Ni-plated steel foil (Example 7), Zn-plated steel foil (Example 8), and Cu-plated steel foil (Example 9) were the best in adhesiveness, that is, they had the highest level of flexibility. The metal substrates provided with the Al-containing metal layers according to Embodiment 1 (Example 10) and Embodiment 2 (Example 11) have sufficient adhesiveness though their performances are inferior. In Examples 13 and 14, the surface smoothnesses of the metals were out of the preferred range explained before (Ra of 20 to 80 nm), therefore the adhesiveness fell a bit. In contrast, in the polyimide layer-containing flexible substrates according to Examples 5 to 11 in which polyimide layers were formed on the metal substrates by cast method, the adhesiveness was improved by an anchor effect.

TABLE 3
Results of Evaluation

| | | | Thermal | | | | | | |
|---|---|---|---|---|---|---|---|---|---|
| | | | expansion | Smoothness | | | | | |
| | Metal substrate | | coefficient | of surface | Adhesiveness | | Corrosion | Corrosion | |
| | configuring polyimide | | of metal | of metal | Results of | | resistance | resistance | |
| | layer-containing | | substrate | substrate | Evaluation of | | (end faces | (end faces | Contamination |
| | flexible substrate | | (ppm/K) | Ra (nm) | cbaracteristic | Peeled part | protected) | not protected) | by metal |
| Ex. 5 | Ordinary steel | | 11 | 60 | Very very | Polyimide/metal | Good | Poor | Good |
| | | | | | good | substrate | | | |
| Ex. 6 | SUS foil | | 11 | 40 | Very very | Polyimide/metal | Extremely | Extremely | Good |
| | | | | | good | substrate | good | good | |
| Ex. 7 | Ni-plated steel foil | | 12 | 50 | Very very | Polyimide/plating | Extremely | Good | Very |
| | | | | | good | layer | good | | good |
| Ex. 8 | Zn-plated steel foil | | 12 | 45 | Very very | Polyimide/plating | Extremely | Good | Very |
| | | | | | good | layer | good | | good |
| Ex. 9 | Cu-plated steel foil | | 12 | 55 | Very very | Polyimide/plating | Very very | Good | Very |
| | | | | | good | layer | good | | good |
| Ex. 10 | Al-plated | Product | 13 | 20 | Very good | Plating layer/ | Very good | Good | Very |
| | steel foil | corresponding | | | | metal foil (ferrite) | | | good |
| | | to Embodiment 1 | | | | | | | |
| Ex. 11 | | Product | 13 | 80 | Very good | Plating layer/ | Very good | Good | Very |
| | | corresponding | | | | metal foil (ferrite) | | | good |
| | | to Embodiment 2 | | | | | | | |
| Ex. 12 | | Product | 13 | 20 | Fair | Plating layer/metal | Very good | Good | Very |
| | | corresponding | | | | foil (ferrite) | | | good |
| | | to prior art | | | | | | | |

| | | | | | | | | |
|---|---|---|---|---|---|---|---|---|
| Ex. 13 | Ordinary steel foil | 11 | 90 | Barely | Polyimide/metal | Good | Poor | Good |
| | | | | fair | substrate | | | |
| Ex. 14 | SUS foil | 11 | 15 | Barely | Polyimide/metal | Extremely | Extremely | Good |
| | | | | fair | substrate | good | good | |

Further, the corrosion resistances of 10 types of polyimide layer-containing flexible substrates in Examples 5 to 14 described above were evaluated by a salt spray test (SST). Note that, a case where the end faces were protected by a seal was described as “end faces protected” and a case where the end faces were not particularly protected by a seal or the like and was tested in an exposed state was described as “end faces not protected”. Note that, the salt water during the test was applied from the surface on which the polyimide layer was not laminated (back surface). In Table 3, a 3% NaCl aqueous solution kept at 45° C. was sprayed. A case where no corrosion could be visually confirmed after 336 hours or more was described as “extremely good”, a case where it could not be confirmed for 240 hours or more was described as “very very good”, a case where it could not be confirmed for 168 hours or more was described as “very good”, a case where it could not be confirmed for 100 hours or more was described as “good”, and a case less than the former was described as “poor”.

Further, using the above 10 types of polyimide layer-containing flexible substrates, the same method as that in Example 1 was used to prepare flexible solar cells and analyze the metal values (contamination of metal) in the polyimide layers and photovoltaic conversion layers. In Table 3, a case where there was no contamination in either of the polyimide layer or photovoltaic conversion layer is described as “very good”, a case where there is contamination in only the polyimide layer is described as “good”, and a case where there is contamination in both of the polyimide layer and the photovoltaic conversion layer is described as “poor”.

As apparent from Table 3, with SUS foil, metal substrate provided with the Ni-containing metal layer (Ni-plated steel foil), and metal substrate provided with the Zn-containing metal layer (Zn-plated steel foil), the corrosion resistance in the case of protection of the end faces was extremely good. The metal substrate provided with the Cu-containing metal layer (Cu-plated steel foil) and the metal substrate provided with the Al-containing metal layer (Al-plated steel foil) are inferior in performances to those described above, but have sufficient corrosion resistance in the case of presence of protection of the end faces. In particular, the SUS foil exhibited a good corrosion resistance even in the case of no protection of the end faces. In the case of no protection of the end faces, the metal substrate provided with the Ni-containing metal layer (Ni-plated steel foil), metal substrate provided with the Zn-containing metal layer (Zn-plated steel foil), metal substrate provided with the Cu-containing metal layer (Cu-plated steel foil), and metal substrate provided with the Al-containing metal layer (Al-plated steel foil) were inferior in performances to the SUS foil, but exhibited practically sufficient performances better than those of ordinary steel foil. Further, with ordinary steel foil and SUS foil, no contamination of metal into the photovoltaic conversion layer was seen. With a metal substrate provided with an Ni-containing metal layer (Ni-plated steel foil), a metal substrate provided with the Zn-containing metal layer (Zn-plated steel foil), metal substrate provided with the Cu-containing metal layer (Cu-plated steel foil), and metal substrate provided with the Al-containing metal layer (Al-plated steel foil), no contamination of metal was confirmed in any of the polyimide layer and photovoltaic conversion layer.

### REFERENCE SIGNS LIST

1 metal foil (steel layer), 2 metal layer or alloy layer, 3 polyimide layer, 4 Fe—Al-based alloy layer, 5 metal substrate, 6 bottom electrode (back electrode), 7 photovoltaic conversion layer (light-absorbing layer), 8 transparent electrode (upper electrode), 9 extraction electrode, 10 polyimide layer-containing flexible substrate, and 20 flexible solar cell

1-15. (canceled)

16. A polyimide layer-containing flexible substrate comprising:
a metal substrate of metal foil made of ordinary steel or stainless steel having a coefficient of thermal expansion in a plane direction of not more than 15 ppm/K and
a polyimide layer which is formed on the metal substrate, has a layer thickness of 1.5 to 100 μm, and has a glass transition point temperature of 300 to 450° C.

17. A polyimide layer-containing flexible substrate comprising:
a metal substrate of metal foil made of ordinary steel or stainless steel having a coefficient of thermal expansion in a plane direction of not more than 15 ppm/K on the surface of which a metal layer comprising one of copper, nickel, zinc, or aluminum or an alloy layer of the same is provided and
a polyimide layer which is formed on the metal layer or the alloy layer, has a layer thickness of 1.5 to 100 μm, and has a glass transition point temperature of 300 to 450° C.

18. The polyimide layer-containing flexible substrate according to claim 17, wherein the metal layer or the alloy layer is an aluminum layer or aluminum alloy layer.

19. The polyimide layer-containing flexible substrate according to claim 16, wherein the coefficient of thermal expansion in the plane direction of the polyimide layer at 100° C. to 250° C. is 15×10⁻⁶/K or less.

20. The polyimide layer-containing flexible substrate according to claim 16, wherein a surface roughness of the surface of the polyimide layer on the side which does not contact the metal substrate is 10 nm or less.

21. The polyimide layer-containing flexible substrate according to claim 16, wherein after heat treatment at 400° C. for 10 minutes, the content of the metal which forms the metal substrate on the surface of the polyimide layer on the side which does not contact the metal substrate is less than a detection limit in measurement according to an emission spectrum detection method.

22. A substrate for a polyimide layer-containing flexible solar cell configured by using a polyimide layer-containing flexible substrate according to claim 16.

23. A flexible solar cell comprising:
a substrate for a polyimide layer-containing flexible solar cell according to claim 22,
a bottom electrode which is formed on the polyimide layer,
a photovoltaic conversion layer which is formed on the bottom electrode, and
a transparent electrode which is formed on the photovoltaic conversion layer.

24. The flexible solar cell according to claim 23, wherein, in the photovoltaic conversion layer, the content of the metal which forms the metal substrate is less than a detection limit in measurement according to an emission spectrum detection method.

25. The flexible solar cell according to claim 23, wherein the content of the metal which forms the metal substrate in the surface of the polyimide layer on the side which does not contact the metal substrate is less than a detection limit in measurement according to the emission spectrum detection method.

26. A method of production of a polyimide layer-containing flexible substrate comprising:
a step of coating a polyimide precursor solution on a metal substrate of metal foil made of ordinary steel or stainless steel having a coefficient of thermal expansion in a plane direction of not more than 15 ppm/K and
a step of heat treating the polyimide precursor solution to cure it by drying and imidization and forming a polyimide layer having a layer thickness of 1.5 to 100 μm and having a glass transition point temperature of 300 to 450° C.

27. A method of production of a polyimide layer-containing flexible substrate comprising:
a step of forming on the surface of metal foil made of ordinary steel or stainless steel having a coefficient of thermal expansion in a plane direction of not more than 15 ppm/K a metal layer comprising one of copper, nickel, zinc, or aluminum or an alloy layer of the same to form a metal substrate,
a step of coating a polyimide precursor solution on the metal layer or the alloy layer of the same, and
a step of heat treating the polyimide precursor solution to cause curing by drying and imidization and thereby to form a polyimide layer having a layer thickness of 1.5 to 100 μm and glass transition point temperature of 300 to 450° C.

28. The method of production of a polyimide layer-containing flexible substrate according to claim 27 which forms an aluminum layer or aluminum alloy layer as the metal layer or the alloy layer in the step of forming on the surface of the metal foil the metal layer or alloy layer of the same to form the metal substrate.

29. A method of production of a substrate for a polyimide layer-containing flexible solar cell which uses the method of production of a polyimide layer-containing flexible substrate according to claim 26 to produce a substrate for a polyimide layer-containing flexible solar cell which uses that polyimide layer-containing flexible substrate.

30. A method of production of a flexible solar cell comprising:
a step of forming a bottom electrode on a polyimide layer of a substrate for a polyimide layer-containing flexible solar cell which is produced according to the method of production of the substrate for a polyimide layer-containing flexible solar cell according to claim 29,
a step of forming a photovoltaic conversion layer on the bottom electrode, and
a step of forming a transparent electrode on the photovoltaic conversion layer.

31. The polyimide layer-containing flexible substrate according to claim 16, wherein said polyimide layer is comprised of a reaction product of a tetracarboxylic acid compound and diamino compound and said tetracarboxylic acid compound is a structure represented by O(CO)₂AR₁(CO)₂O, where Ar₁ is selected from a tetravalent aromatic group represented by the following chemical formula (2):

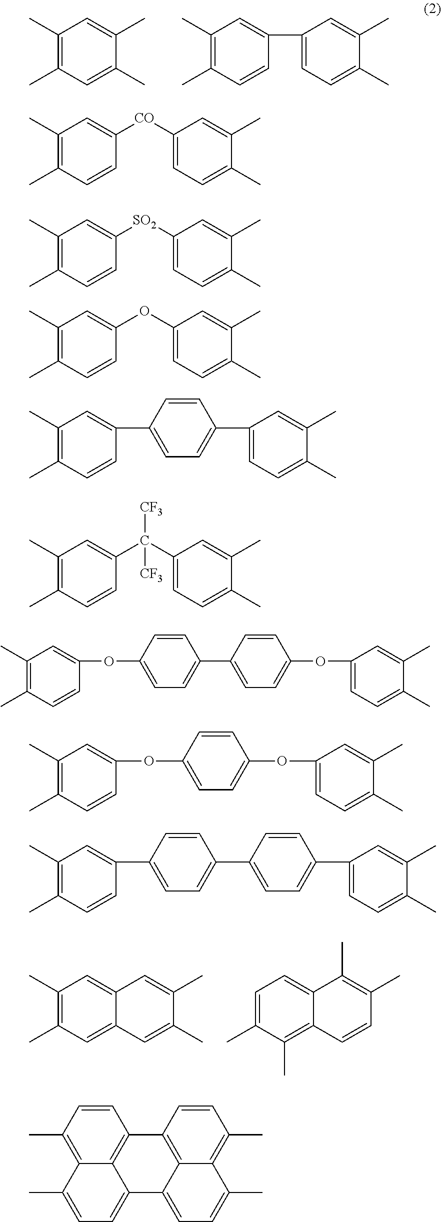

32. The polyimide layer-containing flexible substrate according to claim 31, wherein said tetracarboxylic acid compound is selected from pyromellitic dianhydride (PMDA), 3,3′,4,4′-biphenyl tetracarboxylic acid dianhydride (BPDA), 3,3′4,4′-benzophenone tetracarboxylic acid dianhydride (BTDA), 3,3′4,4′-diphenylsulfone tetracarboxylic acid dianhydride (DSDA), and 4,4′-oxidiphthalic dianhydride (ODPA).

33. The polyimide layer-containing flexible substrate according to claim 31, wherein said tetracarboxylic acid compound is selected from pyromellitic dianhydride (PMDA) and 3,3′,4,4′-biphenyl tetracarboxylic acid dianhydride (BPDA).

34. The polyimide layer-containing flexible substrate according to claim 16, wherein said polyimide layer is comprised of a reaction product of a tetracarboxylic acid compound and diamino compound and said diamino compound is a structure represented by NH₂—Ar₂—NH₂, where Ar₂ is selected from a tetravalent aromatic group represented by the following chemical formula (3):

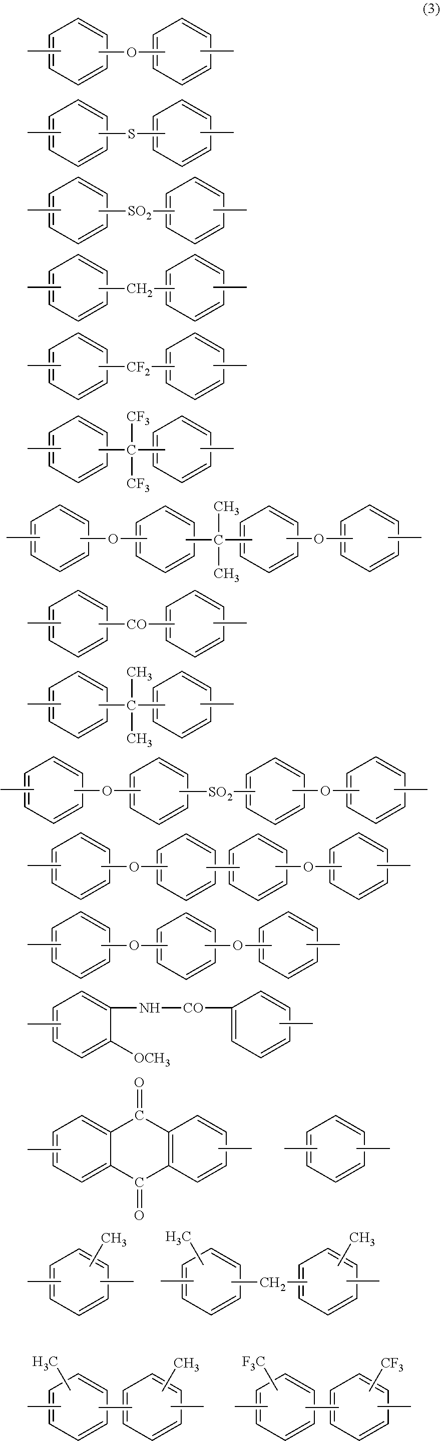

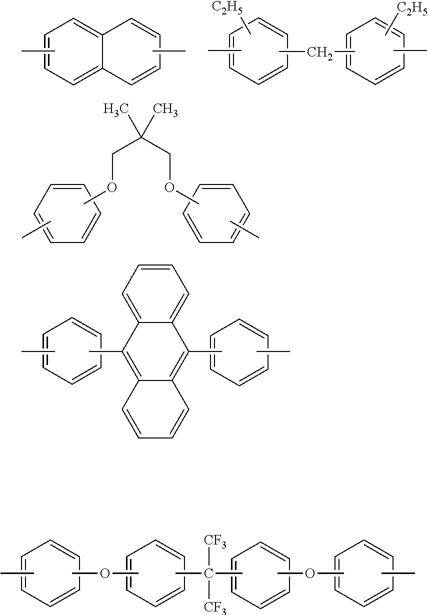

35. The polyimide layer-containing flexible substrate according to claim 34, wherein said diamino compound is selected from diaminodiphenylether (DAPE), 2′-methoxy-4,4′-diaminobenzanilide (MABA), 2,2′-dimethyl-4,4′-diaminobiphenyl (m-TB), paraphenylenediamine (P-PDA), 1,3-bis(4-aminophenoxy)benzene (TPE-R), 1,3-bis(3-aminophenoxy)benzene (APB), 1,4-bis(4-aminophenoxy)benzene (TPE-Q), and 2,2-bis[4-(4-aminophenoxyl)phenyl]propane (BAPP).

36. The polyimide layer-containing flexible substrate according to claim 34, wherein said diamino compound is selected from 2,2′-dimethyl-4,4′-diaminobiphenyl (m-TB) and 2,2-bis[4-(4-aminophenoxyl)phenyl]propane (BAPP).
